(19) United States
(12) Patent Application Publication
(10) Pub. No.: US 2024/0347522 A1
(43) Pub. Date: Oct. 17, 2024

(54) SEMICONDUCTOR DEVICE

(71) Applicant: Semiconductor Energy Laboratory Co., Ltd., Atsugi-shi, Kanagawa-ken (JP)

(72) Inventors: Shunpei YAMAZAKI, Setagaya (JP); Hajime KIMURA, Atsugi (JP)

(21) Appl. No.: 18/294,186

(22) PCT Filed: Jul. 29, 2022
(86) PCT No.: PCT/IB2022/057030

§ 371 Date: Feb. 1, 2024

(30) Foreign Application Priority Data
Aug. 11, 2021 (JP) 2021-131356

(51) Int. Cl. H01L 25/16; G06V 40/13; H01L 25/075; H01L 27/12; H01L 29/786; H01L 33/50

(52) U.S. Cl. CPC H01L 25/167; H01L 25/0753; H01L 27/1225; H01L 27/1251; H01L 29/78648; H01L 29/78675; H01L 29/7869; H01L 33/50; G06V 40/1318

(57) ABSTRACT

One embodiment of the present invention provides a display apparatus having an image capturing function. After a light-emitting diode is fabricated over a first substrate, the light-emitting diode is picked up and mounted over a second substrate. In addition, a light-receiving element is also picked up and mounted over the second substrate which the light-emitting diode is mounted over; a plurality of the light-emitting diodes are arranged so as to surround the light-receiving element, and the display apparatus including a light-receiving region in a gap between the light-emitting regions is achieved.

### TECHNICAL FIELD

One embodiment of the present invention relates to a semiconductor device and an electronic apparatus.

Note that one embodiment of the present invention is not limited to the above technical field. Examples of a technical field of one embodiment of the present invention disclosed in this specification and the like include a semiconductor device, a display apparatus, a light-emitting apparatus, a power storage device, a memory device, an electronic apparatus, a lighting device, an input device, an input/output device, a driving method thereof, and a fabricating method thereof.

In this specification and the like, a semiconductor device refers to a device that utilizes semiconductor characteristics, and means a circuit including a semiconductor element (e.g., a transistor, a diode, or a photodiode), a device including the circuit, and the like. The semiconductor device also means all devices that can function by utilizing semiconductor characteristics. For example, an integrated circuit, a chip including an integrated circuit, and an electronic component including a chip in a package are examples of the semiconductor device. Moreover, a memory device, a display apparatus, a light-emitting apparatus, a lighting device, an electronic apparatus, and the like themselves may be semiconductor devices and may each include a semiconductor device.

### BACKGROUND ART

In recent years, display apparatuses have been required to have higher resolution in order to display high-definition images. In addition, information terminal devices such as smartphones, tablet terminals, and laptop PCs (personal computers) have been required to have lower power consumption as well as higher resolution display. Furthermore, display apparatuses have been required to have a variety of functions such as a touch panel function and a function of capturing images of fingerprints for authentication, in addition to a function of displaying images.

Light-emitting apparatuses including light-emitting elements have been developed as display apparatuses, for example. Light-emitting elements (also referred to as EL elements) utilizing an electroluminescence (also referred to as EL) phenomenon have features such as ease of reduction in thickness and weight, high-speed response to an input signal, and driving with a direct-constant voltage source, and have been used in display apparatuses. For example, Patent Document 1 discloses a display apparatus that functions as a touch panel and includes an organic EL element.

Patent Document 2 discloses an example of a display panel including a micro-LED (Light Emitting Diode).

### REFERENCE

### Patent Document

[Patent Document 1] WO2020/148604
[Patent Document 2] WO2019/220265

### SUMMARY OF THE INVENTION

### Problems to be Solved by the Invention

An object of one embodiment of the present invention is to provide a display apparatus having an image capturing function. Another object is to provide a high-resolution image capturing device or a high-resolution display apparatus. Another object is to provide a display apparatus or an image capturing device with a high aperture ratio. Another object is to provide an image capturing device or a display apparatus capable of image capturing with high sensitivity. Another object is to provide a display apparatus capable of obtaining biological information such as fingerprints. Another object is to provide a display apparatus that functions as a touch panel. Another object is to provide a display apparatus having an image capturing function which is mounted on a vehicle or the like.

An object of one embodiment of the present invention is to provide a highly reliable display apparatus, a highly reliable image capturing device, or a highly reliable electronic apparatus. An object of one embodiment of the present invention is to provide a display apparatus, an image capturing device, an electronic apparatus, or the like that has a novel structure. An object of one embodiment of the present invention is to reduce at least one of problems of the conventional technique.

Note that the description of these objects does not preclude the existence of other objects. Note that one embodiment of the present invention does not have to achieve all the objects. Note that objects other than these can be derived from the description of the specification, the drawings, the claims, and the like.

### Means for Solving the Problems

After a light-emitting diode (hereinafter, also referred to as an LED) is fabricated over a first substrate, the light-emitting diode is picked up and mounted over a second substrate. In addition, a light-receiving element is also picked up and mounted over the second substrate which the light-emitting diode is mounted over; a plurality of light-emitting diodes are arranged to surround the light-receiving element, whereby a display apparatus having a light-receiving region in a gap between light-emitting regions is achieved.

In the case where a light-emitting diode is fabricated, a semiconductor substrate or a sapphire substrate is used. A light-emitting diode is manufactured by a known method on a semiconductor substrate (a single crystal silicon substrate or a silicon carbide substrate) or a sapphire substrate used as an initial growth substrate.

In order to obtain emission colors of red, blue, and green for full-color display, substrates are prepared for the respective colors. In that case, red light-emitting diodes are manufactured on a first substrate, blue light-emitting diodes are manufactured on a second substrate, and green light-emitting diodes are manufactured on a third substrate. In this case, diodes are picked up and mounted one by one. Alternatively, a certain number of, for example, three kinds of light-emitting diodes are fixed as one set with temporary bonding tape, and then mounted.

In addition, full-color display may be achieved by using three blue light-emitting diodes and color conversion layers which convert emission colors of two of the blue light-emitting diodes into red and green. In the case where this method is used, the three blue light-emitting diodes can be picked up as one set and mounted.

A structure disclosed in this specification is a semiconductor device including a plurality of first terminal electrodes and a plurality of second terminal electrodes over a substrate, a light-emitting diode over the first terminal electrode, and a light-receiving element including a photoelectric conversion layer over the second terminal electrode. The light-emitting diode includes a first electrode and a second electrode. The first electrode overlaps with the first terminal electrode. The first terminal electrode is electrically connected to a driver circuit of the light-emitting diode. The second terminal electrode is electrically connected to a driver circuit of the light-receiving element.

In the above structure, when the light-emitting diode or the light-receiving element is mounted, a terminal electrode provided over the substrate and an electrode of a diode chip are aligned and subjected to bonding, pressure bonding, or the like, and electrically connected to each other in a connection layer. Wire bonding which uses Cu or Au as a wire material can be used. Note that solder, metal nanoparticles (e.g., Cu, Ag, Ni, Sn, or Zn), or an anisotropic conductive film can be used for the connection layer. An anisotropic conductive film (ACF) is a resin material in which conductive particles are dispersed in a thermosetting epoxy resin.

In the above structure, the substrate is a glass substrate, a quartz substrate, a plastic substrate, or a semiconductor substrate.

As a light-receiving element, it is possible to use a photodiode including a region where an n-type dopant or a p-type dopant is added to a single crystal semiconductor substrate in a photoelectric conversion layer, a photodiode including an amorphous semiconductor film (typically, an amorphous silicon film) in a photoelectric conversion layer, a photodiode including a microcrystalline semiconductor film in a photoelectric conversion layer, a photodiode including a polycrystalline semiconductor film (typically, a polysilicon film) in a photoelectric conversion layer, or an organic photodiode including an organic compound in a photoelectric conversion layer.

A semiconductor device may have a structure in which a photodiode is formed on a semiconductor substrate in advance and light-emitting diodes are mounted on the semiconductor substrate, and the structure includes a first light-emitting diode overlapping with a first region of the semiconductor substrate, a second light-emitting diode overlapping with a second region of the semiconductor substrate, and a third light-emitting diode overlapping with a third region of the semiconductor substrate. The semiconductor substrate includes a fourth region which is adjacent to one or more of the first region, the second region, and the third region. The fourth region of the semiconductor substrate includes a photoelectric conversion layer and functions as a light-receiving element.

The semiconductor device with the above structure is a light-emitting diode chip in which a first electrode and a second electrode are provided over the first region and one terminal of the first light-emitting diode is connected to the first electrode or the second electrode.

The above-described semiconductor device includes a light-receiving element between a plurality of light-emitting diodes; in other words, the semiconductor device has a structure including a light-receiving region in a gap between the plurality of light-emitting regions. Thus, since the display region can perform both of display and light reception, the semiconductor device can be used for variety of applied products. Examples include a portable information terminal, a wearable terminal, and an in-vehicle product. Specifically, examples include a portable information terminal having a display screen that can perform recognition by an infrared sensor (IR sensor) and an in-vehicle product such as LiDAR (Light Detection and Ranging). Note that LiDAR includes a vertical cavity surface emitting laser and a CMOS (Complementary Metal Oxide Semiconductor) image sensor which can receive near infrared light.

### Effect of the Invention

A novel display apparatus including a light-receiving element between a plurality of light-emitting elements can be provided.

Note that the description of these effects does not preclude the existence of other effects. Note that one embodiment of the present invention does not need to have all the effects. Note that effects other than these can be derived from the description of the specification, the drawings, the claims, and the like.

### BRIEF DESCRIPTION OF THE DRAWINGS

FIG. 1A1, FIG. 1A2, and FIG. 1A3 are perspective views of manufacturing substrates of light-emitting diodes, and FIG. 1A4 is a perspective view of a manufacturing substrate of light-receiving elements. FIG. 1B is a perspective view of a substrate in the middle of mounting illustrating one embodiment of the present invention.

FIG. 2A and FIG. 2E are cross-sectional views illustrating structure examples of display apparatuses. FIG. 2B to FIG. 2D and FIG. 2F to FIG. 2H are top views illustrating examples of pixels.

FIG. 3A and FIG. 3B are cross-sectional views illustrating structure examples of display apparatuses. FIG. 3C and FIG. 3D are top views illustrating examples of pixels.

FIG. 4A and FIG. 4B are block diagrams of a display panel 200 illustrating one embodiment of the present invention.

FIG. 5A and FIG. 5B are diagrams illustrating circuit structure examples of an imaging pixel.

FIG. 6A to FIG. 6D are diagrams illustrating structure examples of a display pixel.

FIG. 7A, FIG. 7B, and FIG. 7C are structure examples of a light-emitting element.

FIG. 8A1, FIG. 8A2, and FIG. 8A3 are perspective views of manufacturing substrates of light-emitting diodes. FIG. 8B is a perspective view of a substrate in the middle of mounting illustrating one embodiment of the present invention.

FIG. 9A and FIG. 9B are diagrams illustrating Si transistors.

FIG. 10A to FIG. 10D are diagrams illustrating OS transistors.

FIG. 11 is a cross-sectional view illustrating a structure example of a display apparatus.

FIG. 12A to FIG. 12D are diagrams illustrating examples of transistors.

FIG. 13A to FIG. 13F are diagrams illustrating examples of electronic apparatuses.

FIG. 14A to FIG. 14F are diagrams illustrating examples of electronic apparatuses.

### MODE FOR CARRYING OUT THE INVENTION

Embodiments of the present invention will be described in detail below with reference to the drawings. Note that the present invention is not limited to the following description, and it is readily understood by those skilled in the art that modes and details of the present invention can be modified in various ways. In addition, the present invention should not be construed as being limited to the description of the embodiments below.

In the case where there is description “X and Y are connected” in this specification and the like, the case where X and Y are electrically connected, the case where X and Y are functionally connected, and the case where X and Y are directly connected are regarded as being disclosed in this specification and the like. Accordingly, without being limited to a predetermined connection relationship, for example, a connection relationship shown in drawings or texts, a connection relationship other than one shown in drawings or texts is regarded as being disclosed in the drawings or the texts. Each of X and Y denotes an object (e.g., a device, an element, a circuit, a wiring, an electrode, a terminal, a conductive film, or a layer).

For example, in the case where X and Y are electrically connected, one or more elements that allow electrical connection between X and Y (e.g., a switch, a transistor, a capacitor element, an inductor, a resistor, a diode, a display apparatus, a light-emitting device, and a load) can be connected between X and Y. Note that a switch is controlled to be in an on state or an off state. That is, a switch has a function of controlling whether or not current flows by being in a conduction state (on state) or a non-conduction state (off state).

For example, in the case where X and Y are functionally connected, one or more circuits that allow functional connection between X and Y (e.g., a logic circuit (an inverter, a NAND circuit, a NOR circuit, or the like); a signal converter circuit (a digital-analog converter circuit, an analog-digital converter circuit, a gamma correction circuit, or the like); a potential level converter circuit (a power supply circuit (a step-up circuit, a step-down circuit, or the like), a level shifter circuit for changing the potential level of a signal, or the like); a voltage source; a current source; a switching circuit; an amplifier circuit (a circuit that can increase signal amplitude, the amount of current, or the like, an operational amplifier, a differential amplifier circuit, a source follower circuit, a buffer circuit, or the like); a signal generation circuit; a memory circuit; a control circuit; or the like) can be connected between X and Y. For instance, even if another circuit is interposed between X and Y, X and Y are regarded as being functionally connected when a signal output from X is transmitted to Y.

Note that an explicit description that X and Y are electrically connected includes the case where X and Y are electrically connected (i.e., the case where X and Y are connected with another element or another circuit interposed therebetween) and the case where X and Y are directly connected (i.e., the case where X and Y are connected without another element or another circuit interposed therebetween).

It can be expressed as, for example, “X, Y, a source (or a first terminal or the like) of a transistor, and a drain (or a second terminal or the like) of the transistor are electrically connected to each other, and X, the source (or the first terminal or the like) of the transistor, the drain (or the second terminal or the like) of the transistor, and Y are electrically connected to each other in this order”. Alternatively, it can be expressed as “a source (or a first terminal or the like) of a transistor is electrically connected to X, a drain (or a second terminal or the like) of the transistor is electrically connected to Y, and X, the source (or the first terminal or the like) of the transistor, the drain (or the second terminal or the like) of the transistor, and Y are electrically connected to each other in this order”. Alternatively, it can be expressed as “X is electrically connected to Y through a source (or a first terminal or the like) and a drain (or a second terminal or the like) of a transistor, and X, the source (or the first terminal or the like) of the transistor, the drain (or the second terminal or the like) of the transistor, and Y are provided in this connection order”. When the connection order in a circuit structure is defined by an expression similar to the above examples, a source (or a first terminal or the like) and a drain (or a second terminal or the like) of a transistor can be distinguished from each other to specify the technical scope. Note that these expressions are examples and the expression is not limited to these expressions. Here, X and Y each denote an object (e.g., a device, an element, a circuit, a wiring, an electrode, a terminal, a conductive film, or a layer).

Even when independent components are electrically connected to each other in a circuit diagram, one component has functions of a plurality of components in some cases. For example, when part of a wiring also functions as an electrode, one conductive film has functions of both components: a function of the wiring and a function of the electrode. Thus, electrical connection in this specification includes, in its category, such a case where one conductive film has functions of a plurality of components.

In this specification and the like, a “capacitor element” can be, for example, a circuit element having an electrostatic capacitance value higher than 0 F, a region of a wiring having an electrostatic capacitance value higher than 0 F, parasitic capacitance, or gate capacitance of a transistor. Therefore, in this specification and the like, a “capacitor element” includes not only a circuit element that has a pair of electrodes and a dielectric between the electrodes, but also parasitic capacitance generated between wirings, gate capacitance generated between a gate and one of a source and a drain of a transistor, and the like. The terms “capacitor element”, “parasitic capacitance”, “gate capacitance”, and the like can be replaced with the term “capacitance” and the like; conversely, the term “capacitance” can be replaced with the terms “capacitor element”, “parasitic capacitance”, “gate capacitance”, and the like. The term “pair of electrodes” of “capacitor” can be replaced with “pair of conductors”, “pair of conductive regions”, “pair of regions”, and the like. Note that the electrostatic capacitance value can be higher than or equal to 0.05 fF and lower than or equal to 10 pF, for example. As another example, the electrostatic capacitance value may be higher than or equal to 1 pF and lower than or equal to 10 μF.

In this specification and the like, a transistor includes three terminals called a gate, a source, and a drain. The gate is a control terminal for controlling the conduction state of the transistor. Two terminals functioning as the source and the drain are input/output terminals of the transistor. One of the two input/output terminals serves as the source and the other serves as the drain depending on the conductivity type (n-channel type or p-channel type) of the transistor and the levels of potentials applied to the three terminals of the transistor. Thus, the terms “source” and “drain” can be replaced with each other in this specification and the like. Furthermore, in this specification and the like, expressions “one of a source and a drain” (or a first electrode or a first terminal) and “the other of the source and the drain” (or a second electrode or a second terminal) are used in the description of the connection relationship of a transistor. Depending on the transistor structure, a transistor may include a back gate in addition to the above three terminals. In this case, in this specification and the like, one of the gate and the back gate of the transistor may be referred to as a first gate and the other of the gate and the back gate of the transistor may be referred to as a second gate. Moreover, the terms “gate” and “back gate” can be replaced with each other in one transistor in some cases. In the case where a transistor includes three or more gates, the gates may be referred to as a first gate, a second gate, and a third gate, for example, in this specification and the like.

In this specification and the like, a “node” can be referred to as a terminal, a wiring, an electrode, a conductive layer, a conductor, an impurity region, or the like depending on the circuit structure, the device structure, or the like. Furthermore, a terminal, a wiring, or the like can be referred to as a “node”.

Ordinal numbers such as “first”, “second”, and “third” in this specification and the like are used to avoid confusion among components. Thus, the ordinal numbers do not limit the number of components. In addition, the ordinal numbers do not limit the order of components. For example, a “first” component in one embodiment in this specification and the like can be referred to as a “second” component in other embodiments, the SCOPE OF CLAIMS, or the like. For another example, a “first” component in one embodiment in this specification and the like can be omitted in other embodiments, the SCOPE OF CLAIMS, or the like.

In this specification and the like, terms for describing arrangement, such as “over”, “under”, “above”, and “below” are sometimes used for convenience to describe the positional relationship between components with reference to drawings. The positional relationship between components is changed as appropriate in accordance with a direction in which each component is described. Thus, the positional relationship is not limited to the terms described in the specification and the like, and can be described with another term as appropriate depending on the situation. For example, the expression “an insulator positioned over (on) a top surface of a conductor” can be replaced with the expression “an insulator positioned under (on) a bottom surface of a conductor” when the direction of a drawing illustrating these components is rotated by 180°.

The term “over” or “under” does not necessarily mean that a component is placed directly over or directly under and directly in contact with another component. For example, the expression “electrode B over insulating layer A” does not necessarily mean that the electrode B is formed over and in direct contact with the insulating layer A, and does not exclude the case where another component is provided between the insulating layer A and the electrode B.

Furthermore, the term “overlap”, for example, in this specification and the like does not limit a state such as the stacking order of components. For example, the expression “electrode B overlapping with insulating layer A” does not necessarily mean the state where “electrode B is formed over insulating layer A”, and does not exclude the state where “electrode B is formed under insulating layer A” and the state where “electrode B is formed on the right side (or the left side) of insulating layer A”.

Each of the terms “adjacent” and “proximity” in this specification and the like does not necessarily mean that a component is directly in contact with another component. For example, the expression “electrode B adjacent to insulating layer A” does not necessarily mean that the electrode B is formed in direct contact with the insulating layer A and does not exclude the case where another component is provided between the insulating layer A and the electrode B.

In this specification and the like, the terms “film”, “layer”, and the like can be interchanged with each other depending on the situation. For example, the term “conductive layer” can be changed into the term “conductive film” in some cases. Also, for example, the term “insulating film” can be changed into the term “insulating layer” in some cases. Alternatively, the term “film”, “layer”, or the like is not used and can be interchanged with another term depending on the case or the situation. For example, the term “conductive layer” or “conductive film” can be changed into the term “conductor” in some cases. Alternatively, the term “conductor” can be changed into the term “conductive layer” or “conductive film” in some cases. Furthermore, for example, the term “insulating layer” or “insulating film” can be changed into the term “insulator” in some cases. Also, the term “insulator” can be changed into the term “insulating layer” or “insulating film” in some cases.

In this specification and the like, the term such as “electrode”, “wiring”, or “terminal” does not limit the function of a component. For example, an “electrode” is used as part of a “wiring” in some cases, and vice versa. Furthermore, for example, the term “electrode” or “wiring” also includes the case where a plurality of “electrodes” or “wirings” are formed in an integrated manner. For example, a “terminal” is used as part of a “wiring” or an “electrode” in some cases, and vice versa. Furthermore, the term “terminal” also includes the case where a plurality of “electrodes”, “wirings”, “terminals”, or the like are formed in an integrated manner, for example. Therefore, for example, an “electrode” can be part of a “wiring” or a “terminal”, and a “terminal” can be part of a “wiring” or an “electrode”. Moreover, the term “electrode”, “wiring”, “terminal”, or the like is sometimes replaced with the term “region” depending on the case.

In this specification and the like, the term such as “wiring”, “signal line”, or “power supply line” can be interchanged with each other depending on the case or the situation. For example, the term “wiring” can be changed into the term “signal line” in some cases. As another example, the term “wiring” can be changed into the term “power supply line” or the like in some cases. Conversely, the term such as “signal line” or “power supply line” can be changed into the term “wiring” in some cases. The term “power supply line” or the like can be changed into the term “signal line” or the like in some cases. Conversely, the term “signal line” or the like can be changed into the term “power supply line” or the like in some cases. Moreover, the term “potential” that is applied to a wiring can sometimes be changed into the term such as “signal” depending on the case or the situation. Conversely, the term “signal” or the like can be changed into the term “potential” in some cases.

In this specification, “parallel” indicates a state where two straight lines are placed at an angle greater than or equal to −10° and less than or equal to 10°. Thus, the case where the angle is greater than or equal to −5° and less than or equal to 5° is also included. In addition, “approximately parallel” or “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Thus, the case where the angle is greater than or equal to 85° and less than or equal to 95º is also included. Furthermore, “approximately perpendicular” or “substantially perpendicular” indicates a state where two straight lines are placed at an angle greater than or equal to 60° and less than or equal to 120°.

Note that in this specification and the like, the terms “identical”, “the same”, “equal”, “uniform”, or the like (including synonyms thereof) used in describing calculation values and measurement values contain an error of +20% unless otherwise specified.

Embodiments described in this specification are described with reference to the drawings. Note that the embodiments can be implemented in many different modes, and it will be readily understood by those skilled in the art that the modes and details can be changed in various ways without departing from the spirit and scope thereof. Therefore, the present invention should not be interpreted as being limited to the description in the embodiments. Note that in the structures of the invention in the embodiments, the same reference numerals are used in common for the same portions or portions having similar functions in different drawings, and repeated description thereof is omitted in some cases. Furthermore, the same hatch pattern is used for the portions having similar functions, and the portions are not especially denoted by reference numerals in some cases. Moreover, some components are omitted in a perspective view, a top view, and the like for easy understanding of the drawings in some cases.

In the drawings and the like related to this specification, the size, the layer thickness, or the region is exaggerated for clarity in some cases. Therefore, embodiments of the present invention are not limited to the size, aspect ratio, and the like shown in the drawings. Note that drawings are schematic views of ideal examples, and the embodiments of the present invention are not limited to the shape or the value illustrated in the drawings. For example, variation in signal, voltage, or current due to noise or variation in signal, voltage, or current due to difference in timing can be included.

In the drawings and the like related to this specification, arrows indicating the X direction, the Y direction, and the Z direction are illustrated in some cases. In this specification and the like, the “X direction” is a direction along the X-axis, and the forward direction and the reverse direction are not distinguished in some cases, unless otherwise specified. The same applies to “Y direction” and “Z direction”. The X direction, the Y direction, and the Z direction are directions intersecting with each other. More specifically, the X direction, the Y direction, and the Z direction are directions orthogonal to each other. In this specification and the like, one of the X direction, the Y direction, and the Z direction is referred to as a “first direction” in some cases. Another one of the directions is referred to as a “second direction” in some cases. The remaining one of the directions is referred to as a “third direction” in some cases.

In this specification and the like, when a plurality of components are denoted by the same reference numerals, and in particular need to be distinguished from each other, an identification sign such as “A”, “b”, “_1”, “[n]”, or “[m,n]” is sometimes added to the reference numerals.

### Embodiment 1

In this embodiment, a pixel circuit or a driver circuit is formed over a glass substrate 201, and a plurality of terminal electrodes are formed. A light-emitting element and a light-receiving element are mounted over the formed terminal electrodes, whereby a display apparatus is fabricated.

For the light-emitting element, a light-emitting diode formed on a sapphire substrate is used. The sapphire substrate is used as an initial growth substrate, and a plurality of light-emitting diodes with a desired size are manufactured on the substrate in advance by a known method. Since a material of a light-emitting layer differs from an emission color of the light-emitting diode, the same number of sapphire substrates as the emission colors are prepared.

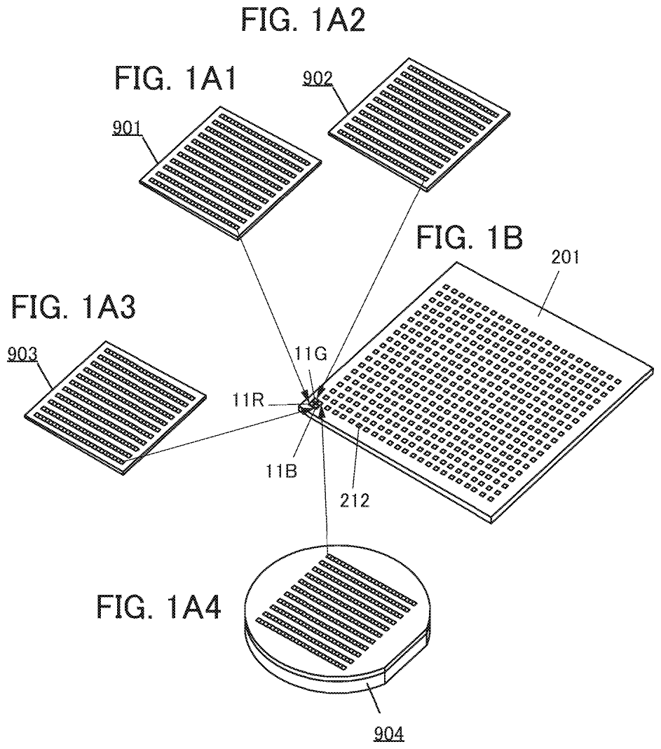

In this embodiment, a substrate 901 of a red light-emitting diode illustrated in FIG. 1A1, a substrate 902 of a green light-emitting diode illustrated in FIG. 1A2, and a substrate 903 of a blue light-emitting diode illustrated in FIG. 1A3 are prepared. On each of the substrates, micro LEDs having a chip size with a flat rectangular shape at least one side of which is less than 0.1 mm or mini LEDs having a chip size with a flat rectangular shape at least one side of which is greater than or equal to 0.1 mm are arranged continuously in the vertical direction and the horizontal direction.

Furthermore, a light-receiving element formed on a single crystal silicon wafer 904 is prepared. Note that FIG. 1A4 is a perspective view of a substrate provided with a light-receiving element.

First, light-receiving elements 212 are mounted over terminal electrodes arranged in a matrix over the glass substrate 201, and then light-emitting diodes are mounted one by one. Note that FIG. 1B is a perspective view of the middle of the mounting, and a red light-emitting diode 11R, a green light-emitting diode 11G, and a blue light-emitting diode 11B are mounted one by one over the glass substrate 201 which the light-receiving elements 212 are mounted over.

In FIG. 1B, three subpixels, the red light-emitting diode 11R, the green light-emitting diode 11G, and the blue light-emitting diode 11B are provided as one pixel to achieve full-color display, and the light-receiving element 212 is additionally provided. Note that positions of the subpixels and the size of the light-emitting region are not particularly limited to the example in FIG. 1B, and may be set as appropriate by a designer.

In addition, full-color display can be achieved by using as a subpixel only the light-emitting diode 11B which emits excitation light in the blue wavelength range (with a peak wavelength longer than or equal to 400 nm and shorter than or equal to 500 nm) and combining with a color conversion layer (also referred to as a phosphor layer).

In addition, full-color display can be performed by using only a ultraviolet light-emitting diode (with a peak wavelength longer than or equal to 200 nm and shorter than 400 nm) as a subpixel and combining with a color conversion layer and a coloring layer. The color conversion layer (or the coloring layer) is a resin layer containing a phosphor pigment (pigment or dye).

The pixel circuit or the driver circuit formed over the glass substrate 201 is formed using a thin film transistor, and an amorphous semiconductor film, a polycrystalline semiconductor film, or an oxide semiconductor film can be used as a material of a semiconductor layer of the thin film transistor. As the polycrystalline semiconductor film, a polycrystalline silicon film (also referred to as a polysilicon film) can be used, and an IGZO film can be used as the oxide semiconductor film. Alternatively, the pixel circuit or the driver circuit can be formed by combining a first thin film transistor using a polycrystalline semiconductor film and a second thin film transistor using an oxide semiconductor film over the glass substrate 201.

After the light-emitting diode and the light-receiving element are mounted, a protective substrate is placed. As the protective substrate, a material which transmits light from the light-emitting diode and a material which does not block light received by the light-receiving element; for example, a quartz substrate, a glass substrate, or a film is used.

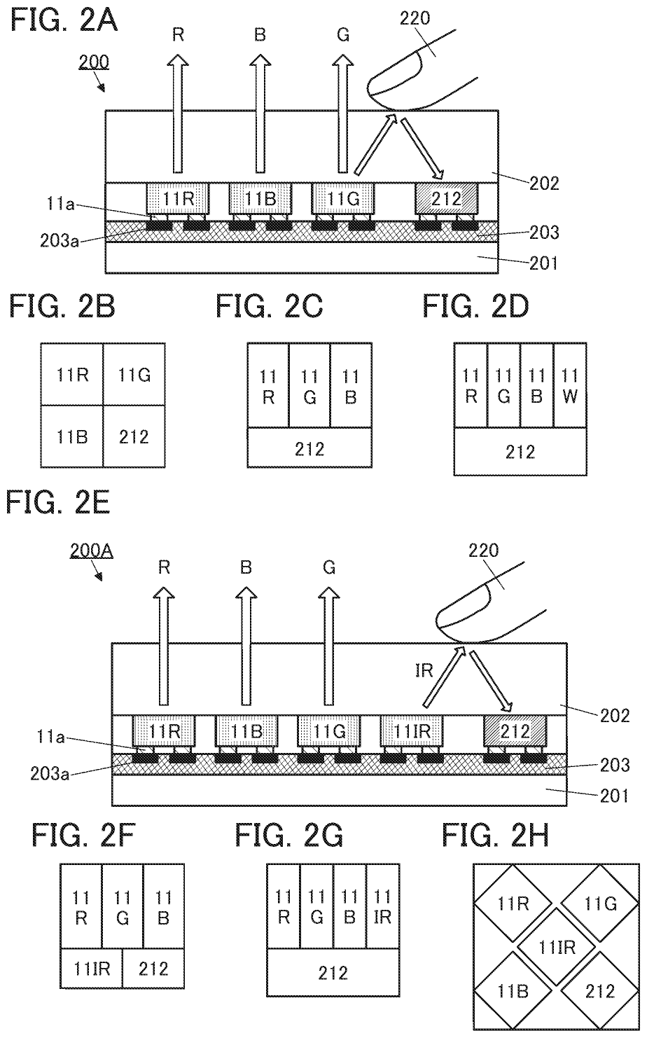

FIG. 2A is a schematic cross-sectional view of the fabricated display panel 200.

### Structure Example 1 of Display Apparatus

### Structure Example 1-1

As illustrated in FIG. 2A, in the display panel 200, a functional layer 203 including a pixel circuit or a driver circuit is provided over the glass substrate 201, the light-emitting diode and the light-receiving element are provided over the functional layer 203, and a protective substrate 202 is provided thereon. The functional layer 203 includes a switch, a transistor, a capacitor, a wiring, and a terminal electrode 203a, and the terminal electrode 203a is electrically connected to an electrode 11a of the light-emitting diode. A connection layer including solder or conductive microparticles can be used for connection between the terminal electrode and electrodes of the light-emitting diode and the light-receiving element.

A gap between the protective substrate 202 and the glass substrate 201 may be filled with a resin or the like, and the gap may be filled with a dry gas. A gap material for holding a gap between the protective substrate 202 and the glass substrate 201 may be placed, or a peripheral portion of the protective substrate 202 and the glass substrate 201 may be fixed with a sealant.

The display panel 200 includes a plurality of pixels arranged in a matrix. One pixel includes one or more subpixels. One subpixel includes one light-emitting diode. For example, the pixel can have a structure including three subpixels (e.g., three colors of R, G, and B or three colors of yellow (Y), cyan (C), and magenta (M)) or four subpixels (e.g., four colors of R, G, B, and white (W) or four colors of R, G, B, and Y). The pixel further includes the light-receiving element 212. The light-receiving element 212 may be provided in all of the pixels or may be provided in some of the pixels. In addition, one pixel may include a plurality of light-receiving elements 212.

FIG. 2A illustrates a finger 220 touching a surface of the protective substrate 202. Part of light emitted from the light-emitting diode 11G is reflected by a contact portion of the protective substrate 202 and the finger 220. In the case where part of the reflected light is incident on the light-receiving element 212, the contact of the finger 220 with the protective substrate 202 can be detected. That is, the display panel 200 can function as a touch panel.

Here, FIG. 2B to FIG. 2D illustrate examples of a pixel that can be used in the display panel 200.

The pixels illustrated in FIG. 2B and FIG. 2C each include the light-emitting diode 11R for red (R), the light-emitting diode 11G for green (G), the light-emitting diode 11B for blue (B), and the light-receiving element 212.

FIG. 2B illustrates an example in which three light-emitting diodes and one light-receiving element are provided in a matrix of 2×2. FIG. 2C illustrates an example in which three light-emitting diodes are arranged in one line and one laterally long light-receiving element 212 is provided below the three light-emitting diodes.

The pixel illustrated in FIG. 2D includes a white (W) light-emitting diode 11W. The white (W) light-emitting diode 11W emits white light when a blue light-emitting diode is used and a yellow phosphor emits light. Here, four kinds of light-emitting diodes are arranged in one line and the light-receiving element 212 is provided below the light-emitting diodes.

Note that the pixel structure is not limited to the above, and a variety of arrangement methods can be employed.

### Structure Example 1-2

A structure example of a display panel 200A including a light-emitting diode emitting visible light, a light-emitting diode emitting infrared light, and a light-receiving element is described below.

The display panel 200A illustrated in FIG. 2E includes a light-emitting diode 11IR in addition to the components illustrated in FIG. 2A as an example. The light-emitting diode 11IR is a light-emitting diode that emits infrared light IR. Moreover, in that case, an element capable of receiving at least the infrared light IR emitted from the light-emitting diode 11IR is preferably used for the light-receiving element 212.

As illustrated in FIG. 2E, when the finger 220 touches the protective substrate 202, the infrared light IR emitted from the light-emitting diode 11IR is reflected by the finger 220 and part of reflected light is incident on the light-receiving element 212, so that the positional information of the finger 220 can be obtained.

FIG. 2F to FIG. 2H illustrate examples of a pixel that can be used in the display panel 200A.

FIG. 2F illustrates an example in which three light-emitting diodes are arranged in one line and the light-emitting diode 11IR and the light-receiving element 212 are arranged below the three light-emitting diodes in a horizontal direction. FIG. 2G illustrates an example in which four kinds of light-emitting diodes including the light-emitting diode 11IR are arranged in one line and the light-receiving element 212 is provided below the light-emitting diodes.

FIG. 2H illustrates an example in which three kinds of light-emitting diodes and the light-receiving element 212 are arranged in all directions with the light-emitting diode 11IR as the center.

Note that in the pixels illustrated in FIG. 2F to FIG. 2H, the positions of the light-emitting diodes can be interchangeable, or the positions of the light-emitting diode and the light-receiving element can be interchangeable.

### Structure Example 1-3

A structure example of a display panel 200B including a light-emitting diode emitting blue light, a light-emitting diode emitting infrared light, and a light-receiving element receiving infrared light is described below.

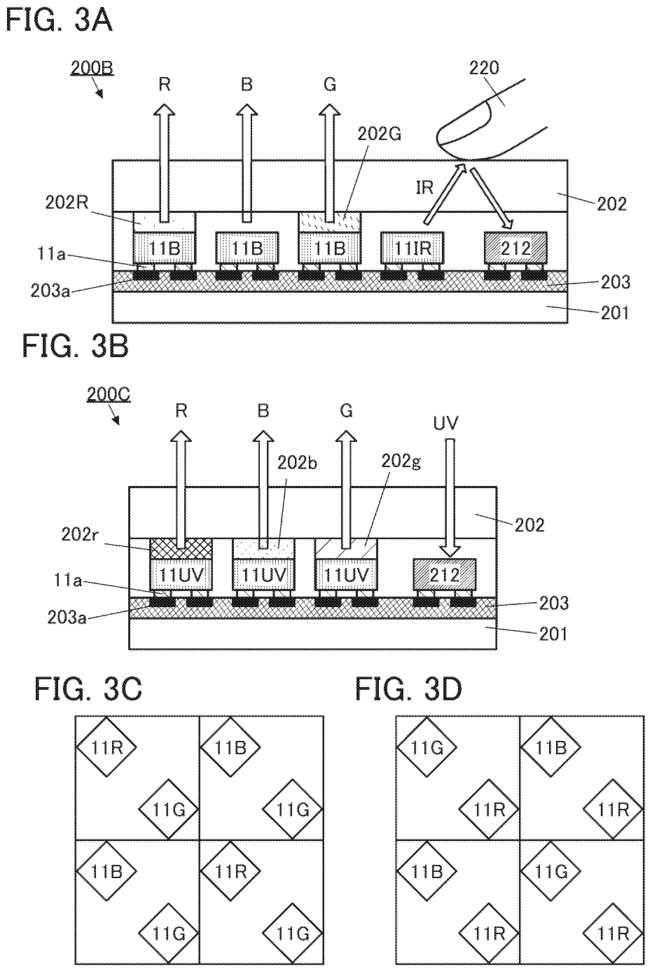

The display panel 200B illustrated in FIG. 3A includes a color conversion layer 202R overlapping with the light-emitting diode 11B. The display panel 200B also includes a color conversion layer 202G overlapping with the light-emitting diode 11B. In mounting, a plurality of the light-emitting diodes 11B can be collectively mounted.

### Structure Example 1-4

A structure example of a display panel 200C including a light-emitting diode emitting ultraviolet light and a light-receiving element receiving ultraviolet light is described below.

The display panel 200C illustrated in FIG. 3B can receive ultraviolet rays and can perform full-color display using only a light-emitting diode 11UV. The light-emitting diode 11UV is a light-emitting diode that emits ultraviolet light UV.

The display panel 200C illustrated in FIG. 3B includes a color conversion layer 202r overlapping with the light-emitting diode 11UV. The display panel 200C also includes a color conversion layer 202b overlapping with the light-emitting diode 11UV. The display panel 200C also includes a color conversion layer 202g overlapping with the light-emitting diode 11UV. In mounting, a plurality of the light-emitting diodes 11UV can be collectively mounted.

### Structure Example 1-5

FIG. 3C illustrates four pixels which employ PenTile arrangement; adjacent two pixels each have a different combination of light-emitting diodes that emit light of different colors. Note that FIG. 3C illustrates top surface shapes of the light-emitting diodes.

The upper left pixel and the lower right pixel in FIG. 3C each include the light-emitting diode 11R and the light-emitting diode 11G. The upper right pixel and the lower left pixel each include the light-emitting diode 11G and the light-emitting diode 11B. That is, in the example illustrated in FIG. 3C, each pixel is provided with the light-emitting diode 11G. Each light-emitting diode forms a subpixel and the following two kinds of pixels are used and arranged: the pixel including a combination of the light-emitting diode 11R and the light-emitting diode 11G and the pixel including a combination of the light-emitting diode 11G and the light-emitting diode 11B.

The top surface shape of the light-emitting diodes is not particularly limited and can be a circular shape, an elliptical shape, a polygonal shape, a polygonal shape with rounded corners, or the like. FIG. 3C illustrates an example in which the top surface shape of the light-emitting diodes is a square tilted at approximately 45° (a diamond shape). Note that the top surface shape of the light-emitting diodes may vary depending on the color thereof, or the light-emitting diodes of some colors or every color may have the same top surface shape.

The sizes of light-emitting regions of the light-emitting diodes may vary depending on the color thereof, or the light-emitting diodes of some colors or every color may have light-emitting regions of the same size. For example, in FIG. 3C, the light-emitting region of the light-emitting diode 11G provided in each pixel may have a smaller area than the light-emitting region of the other elements.

FIG. 3D is a modification example of the pixel arrangement illustrated in FIG. 3C. The upper left pixel and the lower right pixel in FIG. 3D each include the light-emitting diode 11R and the light-emitting diode 11G. The upper right pixel and the lower left pixel each include the light-emitting diode 11R and the light-emitting diode 11B. That is, in the example illustrated in FIG. 3D, each pixel is provided with the light-emitting diode 11R. Each light-emitting diode forms a subpixel and the following two kinds of pixels are used and arranged: the pixel including a combination of the light-emitting diode 11R and the light-emitting diode 11G and the pixel including a combination of the light-emitting diode 11R and the light-emitting diode 11B.

Although a light-receiving element is not illustrated in FIG. 3C and FIG. 3D, there is no particular limitation on the structure as long as a light-receiving element is provided between light-emitting diodes; for example, one light-receiving element is provided between two adjacent subpixels.

As described above, the display apparatus including the display panel of this embodiment can employ any of various types of pixel arrangements.

At least part of this embodiment can be implemented in combination with the other embodiments described in this specification as appropriate.

### Embodiment 2

The display apparatus includes three kinds of light-emitting diodes 11R, 11G, and 11B and a light-receiving device. In addition, the light-emitting diode 11IR that emits near-infrared light as a light source may be included. The light-receiving device has a function of sensing light emitted from a light source of visible light or near-infrared light and reflected by an object. In the case where a light source of near-infrared light is used, light from a first, a second, and a third light-emitting device is emitted through the display portion at high luminance without affecting recognition of the display because the near-infrared light has substantially no luminosity factor.

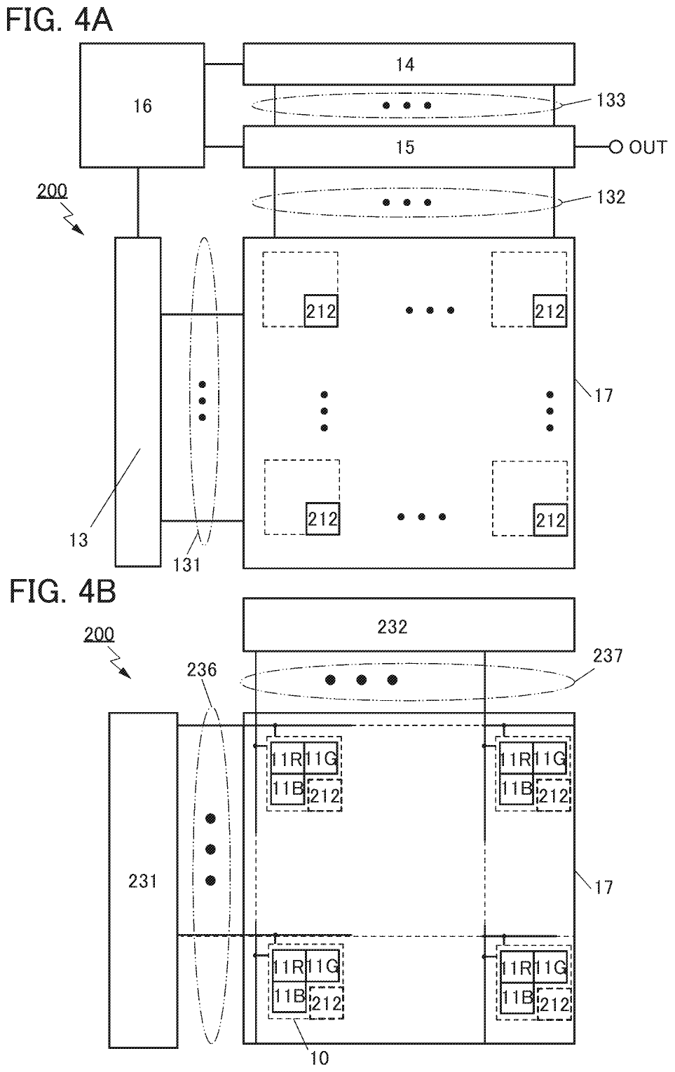

FIG. 4A illustrates a block diagram of the light-receiving element 212 and a driver circuit in the display panel 200. FIG. 4B is a block diagram of a light-emitting diode and a driver circuit in the display panel 200. The light-receiving element 212 and the light-emitting diode each need a driver circuit in order to be driven independently; although the light-emitting element and the light-emitting diode are separately illustrated in FIG. 4A and FIG. 4B for easy understanding, the driver circuits are actually structured with the functional layer 203 illustrated in FIG. 2A or an external driver IC. Note that in FIG. 4A and FIG. 4B, portions corresponding to those in the display panel 200 in FIG. 2A are described using the same reference numerals.

In FIG. 4A, the display panel 200 includes a pixel array 17, the light-receiving element 212, a first driver circuit portion 13, a second driver circuit portion 14, a reading circuit portion 15, a wiring 131, a wiring 132, a wiring 133, and a control circuit portion 16. The display panel 200 may have a structure in which a microlens array including a plurality of microlenses overlap with the light-receiving element 212. The light-receiving element 212 is mounted in the column direction and the row direction so as not to overlap with the light-emitting diode. Note that in FIG. 4A, a terminal OUT represents an output terminal.

As the light-receiving element 212, a pn photodiode or a pin photodiode can be used, for example. Alternatively, a photodiode chip including crystalline silicon (e.g., single crystal silicon, polycrystalline silicon, or microcrystalline silicon) can be used as a light-receiving device. A photoelectric conversion element that detects incident light and generates electric charge can be used as the light-receiving device. The amount of electric charge generated in the light-receiving device is determined depending on the amount of incident light.

As the light-receiving element 212, an organic photodiode including an organic compound in a photoelectric conversion layer can be used. An organic photodiode is easily made thin and lightweight and easily has a large area. In addition, an organic photodiode can be used in a variety of display apparatuses because of its high flexibility in shape and design.

In FIG. 4B, the display panel 200 includes the pixel array 17, the three kinds of light-emitting diodes 11R, 11G, and 11B, a first driver circuit portion 231, and a second driver circuit portion 232. Note that in FIG. 4B, the position where the light-receiving element 212 is mounted is shown with a dotted line, and the positional relation between the light-receiving element 212 and three subpixels, i.e., three kinds of light-emitting diodes 11R, 11G, 11B in one pixel 10 is shown. It can be said that the display panel 200 includes three display pixels and one imaging pixel in one pixel 10.

Note that in this specification, although a minimum unit in which independent operation is performed in one “pixel” is defined as a “subpixel” in the description for convenience, a “pixel” may be replaced with a “region” and a “subpixel” may be replaced with a “pixel”.

For the three kinds of light-emitting diodes 11R, 11G, and 11B, an LED such as a micro LED is used. The micro LED has a chip size with a flat rectangular shape at least one side of which is less than 0.1 mm. Alternatively, a mini LED having a chip size with a flat rectangular shape at least one side of which is greater than or equal to 0.1 mm may be used.

The light-receiving element 212 has a function of sensing light emitted from the green light-emitting diode 11G and reflected by an object. The light-receiving element 212 may be a light-receiving device having sensitivity to near-infrared light. The pixel 10 may further include a light-emitting diode emitting infrared light.

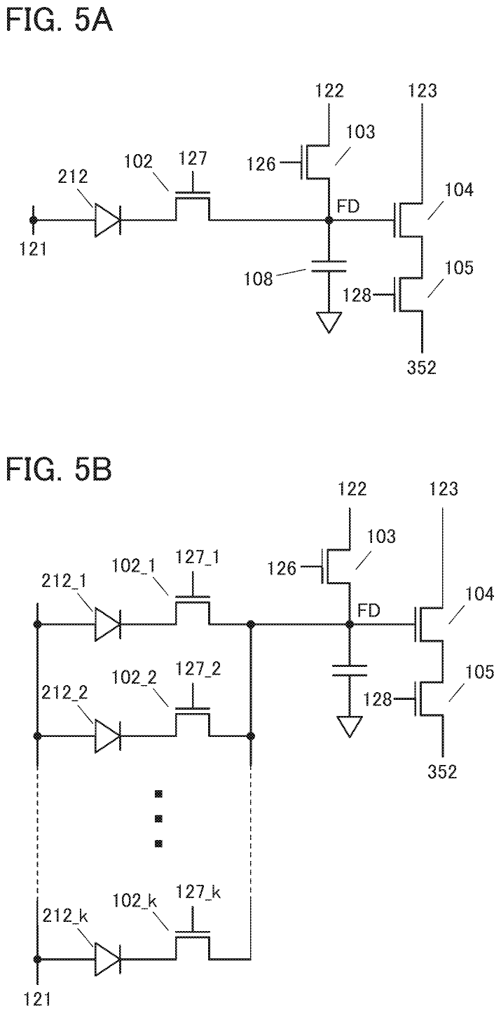

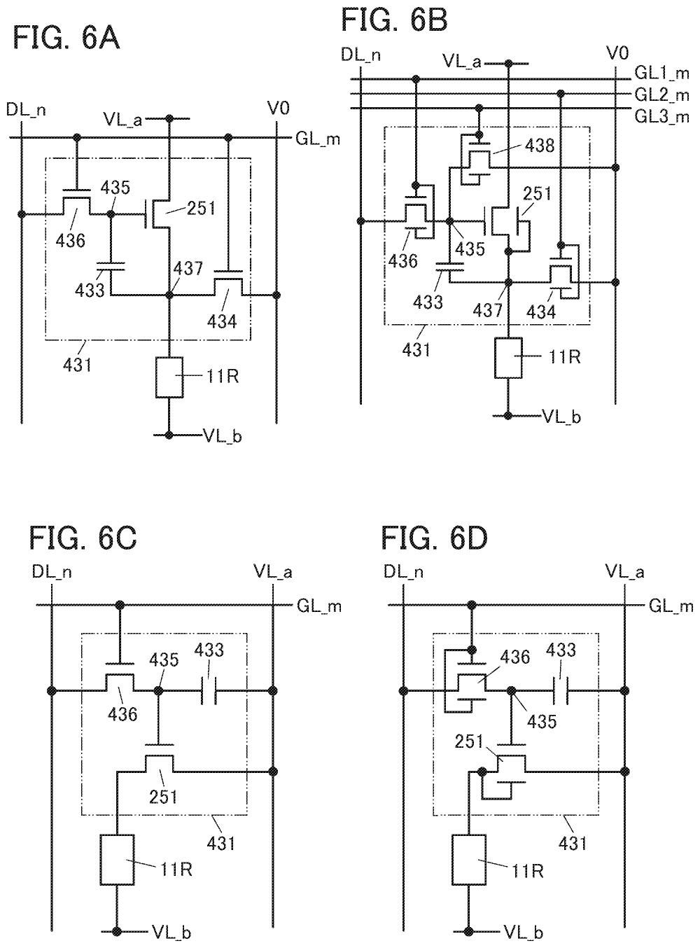

A driver circuit for image capturing by the light-receiving element 212 is provided independently of a driver circuit for performing display. Specifically, a driver circuit for image capturing is illustrated in FIG. 5A and FIG. 5B. In addition, a driver circuit for performing display is illustrated in FIG. 6A, FIG. 6B, FIG. 6C, and FIG. 6D.

### <Circuit Structure Example of Imaging Pixel>

FIG. 5A is a circuit diagram illustrating a circuit structure example of the light-receiving element 212. The driver circuit including the light-receiving element 212 includes a transistor 102, a transistor 103, a transistor 104, a transistor 105, and a capacitor 108. Note that a structure in which the capacitor 108 is not provided may be employed. In addition, a circuit for correcting variation in transistors may be provided so that variation in transistors is externally corrected.

One electrode (cathode) of the light-receiving element 212 is electrically connected to one of a source and a drain of the transistor 102. The other of the source and the drain of the transistor 102 is electrically connected to one of a source and a drain of the transistor 103. The one of the source and the drain of the transistor 103 is electrically connected to one electrode of the capacitor 108. The one electrode of the capacitor 108 is electrically connected to a gate of the transistor 104. One of a source and a drain of the transistor 104 is electrically connected to one of a source and a drain of the transistor 105.

Here, a wiring that connects the other of the source and the drain of the transistor 102, the one electrode of the capacitor 108, and the gate of the transistor 104 is a node FD. The node FD can function as a charge detection unit.

The other electrode (anode) of the light-receiving element 212 is electrically connected to a wiring 121. A gate of the transistor 102 is electrically connected to a wiring 127. The other of the source and the drain of the transistor 103 is electrically connected to a wiring 122. The other of the source and the drain of the transistor 104 is electrically connected to a wiring 123. A gate of the transistor 103 is electrically connected to a wiring 126. The gate of the transistor 105 is electrically connected to a wiring 128. The other electrode of the capacitor 108 is electrically connected to a reference potential line such as a GND wiring, for example. The other of the source and the drain of the transistor 105 is electrically connected to a wiring 352.

The wiring 127, the wiring 126, and the wiring 128 each have a function as a signal line controlling on and off states of each transistors. The wiring 352 has a function as an output line.

The wiring 121, the wiring 122, and the wiring 123 each have a function as a power supply line. In the structure illustrated in FIG. 5A, the cathode side of the light-receiving element 212 is electrically connected to the transistor 102, and the node FD is reset to a high potential and operated. Thus, the wiring 122 is at a high potential (a potential higher than that of the wiring 121).

Although the cathode of the light-receiving element 212 is electrically connected to the node FD in FIG. 5A, the anode side of the light-receiving element 212 may be electrically connected to the one of the source and the drain of the transistor 102. In this case, since the node FD is reset to a low potential in the operation in the structure, the wiring 122 is set to a low potential (a potential lower than that of the wiring 121).

The transistor 102 has a function of controlling the potential of the node FD. The transistor 102 is also referred to as a “transfer transistor”. The transistor 103 has a function of resetting the potential of the node FD. The transistor 103 is also referred to as a “reset transistor”. The transistor 104 functions as a source follower circuit and can output the potential of the node FD as image data to the wiring 352. The transistor 105 has a function of selecting a pixel to which the image data is output. The transistor 104 is also referred to as an “amplifier transistor”. The transistor 105 is also referred to as a “selection transistor”.

The light-receiving element 212 and the transistor 102 are regarded as one group as illustrated in FIG. 5B, and a plurality of groups each including the light-receiving element 212 and the transistor 102 may be connected to the node FD. With the circuit structure illustrated in FIG. 5B, the area occupied by one light-receiving element 212 can be reduced. Thus, the packing density of the light-receiving element 212 can be increased.

In FIG. 5B, the light-receiving element 212 and the transistor 102 in a first group are denoted by a light-receiving element 212_1 and a transistor 102_1. A gate of the transistor 102_1 is electrically connected to a wiring 127_1. The light-receiving element 212 and the transistor 102 in a second group are denoted by a light-receiving element 212_2 and a transistor 102_2. A gate of the transistor 102_2 is electrically connected to a wiring 127_2. The light-receiving element 212 and the transistor 102 of k-th set (k is an integer greater than or equal to 1) are denoted by a light-receiving element 212_k and a transistor 102_k. A gate of the transistor 102_k is electrically connected to a wiring 127_k.

### Circuit Structure Example 1 of Display Pixel

FIG. 6A is a diagram illustrating a circuit structure example of a subpixel in one pixel 10. In this embodiment, a subpixel emitting red light is described as an example. The subpixel includes a display pixel circuit 431 and the light-emitting diode 11R. Other subpixels are a subpixel emitting blue light and a subpixel emitting green light, and three kinds of light-emitting diodes serve as one pixel 10 and are provided in m rows and n columns to form a display region. Note that m and n are each an integer of 1 or more.

The pixel circuit 431 includes a transistor 436, a capacitor element 433, a transistor 251, and a transistor 434. The display pixel circuit 431 is electrically connected to the light-emitting diode 11R.

One of a source electrode and a drain electrode of the transistor 436 is electrically connected to a wiring to which a data signal (also referred to as “video signal”) is supplied (hereinafter, referred to as a signal line DL_n). A gate electrode of the transistor 436 is electrically connected to a wiring to which a gate signal is supplied (hereinafter, referred to as a scan line GL_m). The signal line DL_n and the scan line GL_m correspond to a wiring 237 and a wiring 236 (in FIG. 4B), respectively.

The transistor 436 has a function of controlling the writing of the data signal to a node 435.

One of a pair of electrodes of the capacitor element 433 is electrically connected to the node 435, and the other is electrically connected to a node 437. The other of the source electrode and the drain electrode of the transistor 436 is electrically connected to the node 435.

The capacitor element 433 has a function of a storage capacitor for storing data written to the node 435.

One of a source electrode and a drain electrode of the transistor 251 is electrically connected to a potential supply line VL_a, and the other is electrically connected to the node 437. Furthermore, a gate electrode of the transistor 251 is electrically connected to the node 435.

One of a source electrode and a drain electrode of the transistor 434 is electrically connected to a potential supply line V0, and the other is electrically connected to the node 437. Furthermore, a gate electrode of the transistor 434 is electrically connected to the scan line GL_m.

One of an anode and a cathode of the light-emitting diode 11R is electrically connected to a potential supply line VL_b, and the other is electrically connected to the node 437.

As a power supply potential, a potential on the relatively high potential side or a potential on the relatively low potential side can be used, for example. A power supply potential on the high potential side is referred to as a high power supply potential (also referred to as “VDD”), and a power supply potential on the low potential side is referred to as a low power supply potential (also referred to as “VSS”). A ground potential can be used as the high power supply potential or the low power supply potential. For example, in the case where a ground potential is used as the high power supply potential, the low power supply potential is a potential lower than the ground potential, and in the case where a ground potential is used as the low power supply potential, the high power supply potential is a potential higher than the ground potential.

A high power supply potential VDD is supplied to one of the potential supply line VL_a and the potential supply line VL_b, and a low power supply potential VSS is supplied to the other, for example.

In the display apparatus including the display pixel circuits 431, the display pixel circuits 431 are sequentially selected row by row by the circuit included in the peripheral driver circuit, whereby the transistor 436 and the transistor 434 are turned on and a data signal is written to the node 435.

When the transistor 436 and the transistor 434 are turned off, the display pixel circuit 431 in which the data has been written to the node 435 is brought into a retention state. Furthermore, the amount of current flowing between the source electrode and the drain electrode of the transistor 251 is controlled in accordance with the potential of the data written to the node 435; the light-emitting diode 11R emits red light with a luminance corresponding to the amount of current flow. This operation is sequentially performed row by row; thus, a red image can be displayed. In addition, the light-emitting diode 11B and the light-emitting diode 11G are driven in a similar manner, whereby a full-color image can be displayed.

A circuit for correcting variation in transistors may be provided so that variation in transistors is externally corrected.

### Circuit Structure Example 2 of Display Pixel

FIG. 6B illustrates a modification example of the circuit structure of the display pixel in FIG. 6A. In a circuit structure illustrated in FIG. 6B, the gate electrode of the transistor 436 is electrically connected to a line to which a first scan signal is supplied (hereinafter, referred to as a scan line GL1_m). The gate electrode of the transistor 434 is electrically connected to a line to which a second scan signal is supplied (hereinafter, referred to as a scan line GL2_m).

The circuit structure illustrated in FIG. 6B includes a transistor 438 in addition to the circuit structure illustrated in FIG. 6A. One of a source electrode and a drain electrode of the transistor 438 is electrically connected to the potential supply line V0, and the other is electrically connected to the node 435. A gate electrode of the transistor 438 is electrically connected to a line to which a third scan signal is supplied (hereinafter, referred to as a scan line GL3_m).

The scan line GL1_m corresponds to the wiring 236 illustrated in FIG. 4B. In FIG. 4B, although the wirings corresponding to the scan line GL2_m and the scan line GL3_m are not illustrated, the scan line GL2_m and the scan line GL3_m are electrically connected to the first driver circuit portion 231.

In the case where the light-emitting diode 11R performs black display, for example, both the transistor 434 and the transistor 438 are turned on. Thus, the potential of a source electrode of the transistor 251 is equal to that of the gate electrode thereof. In this manner, a gate voltage of the transistor 251 is set to 0 V, so that current flowing through the light-emitting diode 11R can be blocked.

Furthermore, some or all of the transistors included in the display pixel circuit 431 may be transistors having a back gate. Transistors with a back gate are used as transistors in the circuit structure illustrated in FIG. 6B. For example, a gate and a back gate is electrically connected to each other in each of the transistor 434, the transistor 436, and the transistor 438. In addition, in the transistor 251 illustrated in FIG. 6B, the back gate is electrically connected to the node 437.

In addition, a circuit for correcting variation in transistors may be provided so that variation in transistors is externally corrected.

### Circuit Structure Example 3 of Display Pixel

FIG. 6C illustrates a modification example of a circuit structure of the display pixel illustrated in FIG. 6A. The circuit structure illustrated in FIG. 6C is a structure excluding the transistor 434 and the potential supply line V0 in the circuit structure illustrated in FIG. 6A. For understanding of other components, description of the circuit structure illustrated in FIG. 6A can be referred to. Therefore, the detailed description of the circuit structure in FIG. 6C is omitted to reduce repetitive description.

Furthermore, as described above, some or all of the transistors included in the display pixel circuit 431 may be transistors having a back gate. For example, the transistor 436 may be a transistor having a back gate, and the back gate and the gate thereof may be electrically connected to each other as illustrated in FIG. 6D. As in the transistor 251 illustrated in FIG. 6D, the back gate and one of the source and the drain of the transistor may be electrically connected to each other.

Note that a structure in which the number of wirings is reduced by using one wiring for a common wiring of the light-emitting diodes 11R, 11G, and 11B and a common wiring of the light-receiving element 212 may be employed.

Image capturing data on a fingerprint, a palm print, an iris, or the like can be obtained with the use of the light-receiving element 212. That is, a biological authentication function can be added to the display apparatus. Note that image capturing data may be acquired when an object is made to be in contact with the display apparatus.

In addition, image capturing data on facial expression, eye movement, change of the pupil diameter, or the like of the user can be obtained with the use of the light-receiving element 212. By analysis of the image data, information on the user's physical and mental state can be obtained. On the basis of the information, it is possible to perform operation in accordance with the user's physical and mental state, e.g., to change one or both of display and sound output by the display apparatus. Such operation is effective for devices for VR (Virtual Reality), devices for AR (Augmented Reality), or devices for MR (Mixed Reality).

In addition, a circuit for correcting variation in transistors may be provided so that variation in transistors is externally corrected.

### Embodiment 3

In this embodiment, the structure of the light-emitting diode will be described below. The light-emitting diode chip that is separately cut is referred to as an LED chip 51 in some cases.

There is no particular limitation on the structure of the light-emitting diode; an MIS (Metal Insulator Semiconductor) junction may be used or a homostructure, a heterostructure, a double-heterostructure, or the like having a PN junction or a PIN junction can be used. It is also possible to use a superlattice structure, or a single quantum well structure or a multi quantum well (MQW) structure where thin films producing a quantum effect are stacked. Alternatively, a nanocolumn LED chip may be used.

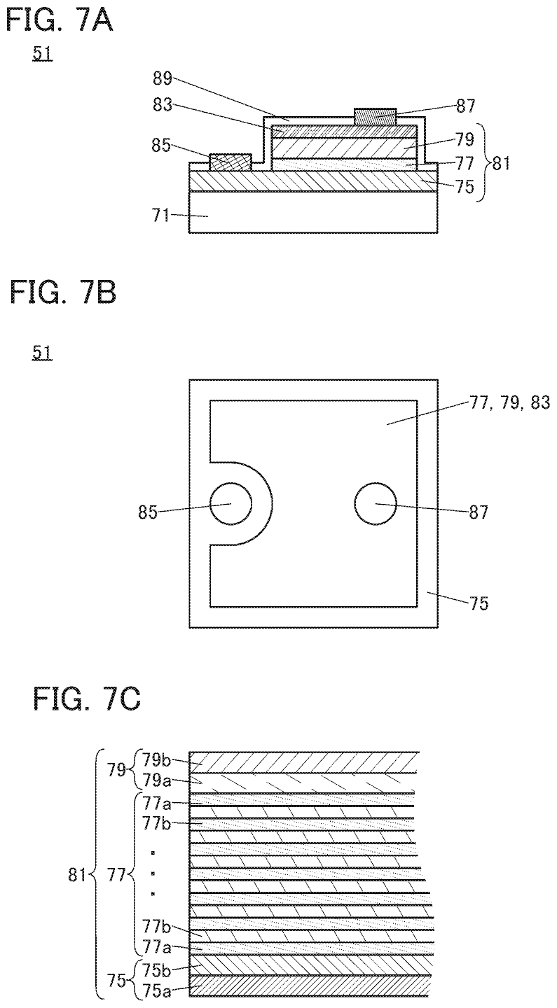

An example of the LED chip is illustrated in FIG. 7A and FIG. 7B. FIG. 7A shows a cross-sectional view of the LED chip 51 and FIG. 7B shows a top view of the LED chip 51. The LED chip 51 includes a semiconductor layer 81 and the like. The semiconductor layer 81 includes an n-type semiconductor layer 75, a light-emitting layer 77 over the n-type semiconductor layer 75, and a p-type semiconductor layer 79 over the light-emitting layer 77. A material that can be used for the p-type semiconductor layer 79 has a larger band gap energy than the light-emitting layer 77 and allows carriers to be trapped in the light-emitting layer 77. Also in the LED chip 51, an electrode 85 functioning as a cathode is provided over the n-type semiconductor layer 75, an electrode 83 functioning as a contact electrode is provided over the p-type semiconductor layer 79, and an electrode 87 functioning as an anode is provided over the electrode 83. In addition, a top surface and side surfaces of the electrode 83 are preferably covered with an insulating layer 89. The insulating layer 89 functions as a protective film of the LED chip 51.

An example of an enlarged view of the semiconductor layer 81 is illustrated in FIG. 7C. As illustrated in FIG. 7C, the n-type semiconductor layer 75 may include an n-type contact layer 75a on a substrate 71 side and an n-type clad layer 75b on the light-emitting layer 77 side. The p-type semiconductor layer 79 may include a p-type clad layer 79a on the light-emitting layer 77 side and a p-type contact layer 79b over the p-type clad layer 79a.

The light-emitting layer 77 can have a multiple quantum well (MQW) structure where a barrier layer 77a and a well layer 77b are stacked multiple times. The barrier layer 77a preferably uses a material having a larger band gap energy than the material for the well layer 77b. Such a structure allows the energy to be trapped in the well layer 77b, thereby improving the quantum efficiency and the emission efficiency of the LED chip 51.

In the LED chip 51 of a face-up type, a light-transmitting material can be used for the electrode 83; for example, an oxide such as ITO (In₂O₃—SnO₂), AZO (Al₂O₃—ZnO), In—Zn oxide (In₂O₃—ZnO), GZO (GeO₂—ZnO), or ICO (In₂O₃—CeO₂) can be used. In the LED chip 51 of a face-up type, light is mainly emitted to the electrode 87 side. In the LED chip 51 of a face-down type, a light-reflecting material can be used for the electrode 83; for example, a metal such as silver, aluminum, or rhodium can be used. In the LED chip 51 of a face-down type, light is mainly emitted to the substrate 71 side.

For the substrate 71, oxide single crystal such as sapphire single crystal (Al₂O₃), spinel single crystal (MgAl₂O₄), ZnO single crystal, LiAlO₂ single crystal, LiGaO₂ single crystal, or MgO single crystal, Si single crystal, SiC single crystal, GaAs single crystal, AlN single crystal, GaN single crystal, boride single crystal such as ZrB₂, or the like can be used. In the LED chip 51 of a face-down type, a light-transmitting material is preferably used for the substrate 71; for example, sapphire single crystal that transmits light can be used.

A buffer layer (not illustrated) may be provided between the substrate 71 and the n-type semiconductor layer 75. The buffer layer has a function of alleviating the difference in lattice constant between the substrate 71 and the n-type semiconductor layer 75.

The LED chip 51 that can be used as the light-emitting diode chip preferably has a horizontal structure where the electrode 85 and the electrode 87 are positioned on the same plane side as illustrated in FIG. 7A. When the electrode 85 and the electrode 87 are provided on the same plane side in the LED chip 51, a terminal electrode can be easily connected thereto and can have a simple structure. The LED chip 51 that can be used as the light-emitting diode chip is preferably of a face-down type. The use of the face-down type LED chip 51 allows light from the LED chip 51 to be efficiently emitted to the display surface side of the display apparatus, so that the display apparatus can have high luminance. A commercial LED chip may be used as the LED chip 51.

A color conversion layer is used in order to obtain white light emission. As a phosphor included in the color conversion layer, an organic resin layer having a surface on which a phosphor is printed or which is coated with a phosphor, or an organic resin layer mixed with a phosphor can be used. The color conversion layer can be formed using a material that is excited by light emitted from the LED chip 51 and emits light of a complementary color of the emission color of the LED chip 51. With such a structure, light emitted from the light-emitting diode chip and light emitted from the phosphor are combined, so that the color conversion layer can emit white light.

For example, a structure where white light is emitted from the color conversion layer can be obtained with use of the LED chip 51 emitting blue light and a phosphor emitting yellow light, which is a complementary color of blue. The LED chip 51 that can emit blue light is typically a diode made of Group 13 nitride-based compound semiconductor, e.g., a diode containing a GaN-based material which is represented by a formula, InₓAl_{y}Ga_{1-x-y}N (x is greater than or equal to 0 and less than or equal to 1, y is greater than or equal to 0 and less than or equal to 1, and x+y is greater than or equal to 0 and less than or equal to 1). Typical examples of the phosphor that is excited by blue light and emits yellow light include Y₃Al₅O₁₂:Ce (YAG:Ce) and (Ba,Sr,Mg)₂SiO₄:Eu,Mn.

For example, a structure where white light is emitted from the color conversion layer can be obtained with use of the LED chip 51 emitting blue-green light and a phosphor emitting red light, which is a complementary color of blue-green.

The color conversion layer may include a plurality of kinds of phosphors and each of the phosphors may emit light of a different color. For example, a structure where white light is emitted from the color conversion layer can be obtained with use of the LED chip 51 emitting blue light, a phosphor emitting red light, and a phosphor emitting green light. Typical examples of the phosphor that is excited by blue light and emits red light include (Ca,Sr)S:Eu and Sr₂Si₇Al₃ON₁₃:Eu. Typical examples of the phosphor that is excited by blue light and emits green light include SrGa₂S₄:Eu and Sr₃Si₁₃Al₃O₂N₂₁:Eu.

A structure where white light is emitted from the color conversion layer can be obtained with use of the LED chip 51 emitting near-ultraviolet light or violet light, a phosphor emitting red light, a phosphor emitting green light, and a phosphor emitting blue light. Typical examples of the phosphor that is excited by near-ultraviolet light or violet light and emits red light include (Ca,Sr)S:Eu, Sr₂Si₇Al₃ON₁₃:Eu, and La₂O₂S:Eu. Typical examples of the phosphor that is excited by near-ultraviolet light or violet light and emits green light include SrGa₂S₄:Eu and Sr₃Si₁₃Al₃O₂N₂₁:Eu. Typical examples of the phosphor that is excited by near-ultraviolet light or violet light and emits blue light include Sr₁₀(PO₄)₆Cl₂:Eu and (Sr,Ba,Ca)₁₀(PO₄)₆Cl₂:Eu.

Note that near-ultraviolet light has a maximum peak at a wavelength of 200 nm to 380 nm in an emission spectrum. Violet light has a maximum peak at a wavelength of 380 nm to 430 nm in an emission spectrum. Blue light has a maximum peak at a wavelength of 430 nm to 490 nm in an emission spectrum. Green light has a maximum peak at a wavelength of 490 nm to 550 nm in an emission spectrum. Yellow light has a maximum peak at a wavelength of 550 nm to 590 nm in an emission spectrum. Red light has a maximum peak at a wavelength of 640 nm to 770 nm in an emission spectrum.

In the case where the color conversion layer includes a phosphor emitting yellow light and the LED chip 51 emitting blue light is used, light emitted from the LED chip 51 preferably has a maximum peak at a wavelength of 330 nm to 500 nm in an emission spectrum, further preferably a maximum peak at a wavelength of 430 nm to 490 nm, and still further preferably a maximum peak at a wavelength of 450 nm to 480 nm. This allows efficient excitation of the phosphor. When light emitted from the LED chip 51 has a maximum peak at 430 nm to 490 nm in an emission spectrum, blue light that is excitation light and yellow light that is from the phosphor can be mixed to be white light. Furthermore, when light emitted from the LED chip 51 has a maximum peak at 450 nm to 480 nm, white with high purity can be obtained.

The above is the description of the structure example of the LED chip 51.

At least part of this embodiment can be implemented in appropriate combination with the other embodiments described in this specification.

### Embodiment 4

Although Embodiment 1 shows an example where a rectangular sapphire substrate is used, this embodiment shows an example where a single crystal silicon substrate is used. In the case where a single crystal silicon substrate is used, a driver circuit of a light-emitting diode (e.g., a demultiplexer circuit or a digital-analog converter circuit) can be formed, and a driver circuit of a sensor can also be formed.

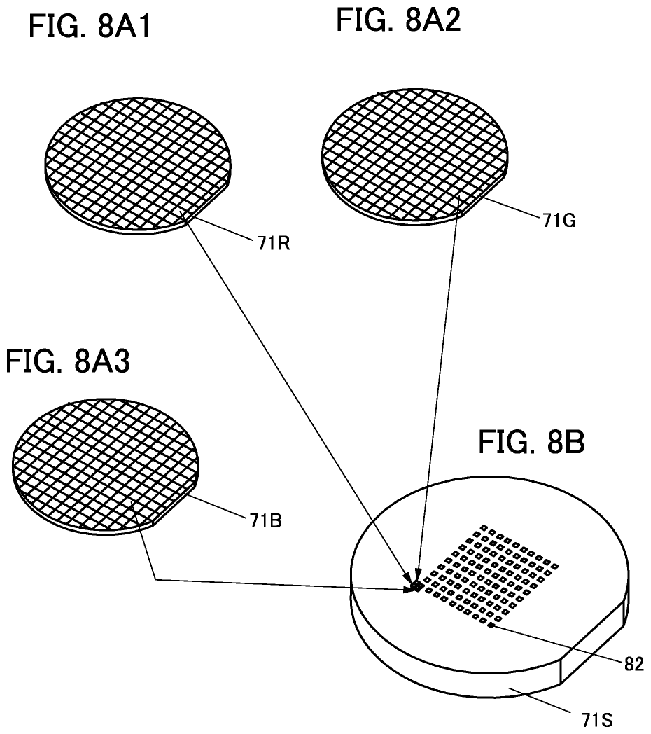

FIG. 8A1 is a perspective view of a single crystal silicon substrate 71R. As a red LED chip, a semiconductor layer including an n-type semiconductor layer, a light-emitting layer, a p-type semiconductor layer, and the like, an electrode functioning as a cathode, and an electrode functioning as an anode are formed on the single crystal silicon substrate 71R.

A plurality of red LED chips are formed on the single crystal silicon substrate 71R, and the single crystal silicon substrate 71R is separated along the LED chip compartments, whereby a plurality of red LED chips can be fabricated.

FIG. 8A2 is a perspective view of a single crystal silicon substrate 71G. As a green LED chip, a semiconductor layer including an n-type semiconductor layer, a light-emitting layer, a p-type semiconductor layer, and the like, an electrode functioning as a cathode, and an electrode functioning as an anode are formed on the single crystal silicon substrate 71G.

A plurality of green LED chips are formed on the single crystal silicon substrate 71G, and the single crystal silicon substrate 71G is separated along the LED chip compartments, whereby a plurality of green LED chips can be fabricated.

FIG. 8A3 is a perspective view of a single crystal silicon substrate 71B. As a blue LED chip, a semiconductor layer including an n-type semiconductor layer, a light-emitting layer, a p-type semiconductor layer, and the like, an electrode functioning as a cathode, and an electrode functioning as an anode are formed on the single crystal silicon substrate 71B.

A plurality of blue LED chips are formed on the single crystal silicon substrate 71B, and the single crystal silicon substrate 71B is separated along the LED chip compartments, whereby a plurality of blue LED chips can be fabricated.

In addition, a CMOS image sensor is formed on a single crystal silicon substrate 71S. The CMOS image sensor can be fabricated with a known technique. A top-illuminated CMOS image sensor is used. Furthermore, a light-receiving region 82 is formed. The light-receiving region 82 may include a microlens or coloring layer in a region overlapping with the light-receiving region 82.

A red LED chip, a green LED chip, and a blue LED chip are mounted so as not to overlap with the light-receiving region 82. FIG. 8B is a perspective view of a state in which light-emitting diodes are picked up one by one and mounted over the single crystal silicon substrate 71S.

In addition, since a red LED chip, a green LED chip, and a blue LED chip are mounted over the single crystal silicon substrate 71S, a terminal electrode and a driver circuit which is electrically connected to the terminal electrode are provided. Needless to say, a driver circuit of the CMOS sensor may be provided over the single crystal silicon substrate 71S. Alternatively, these driver circuits may be formed over another semiconductor substrate and the semiconductor substrates may be electrically connected to each other by bonding.

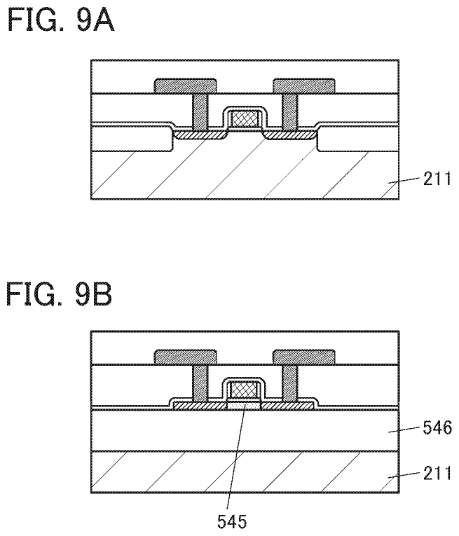

For example, a single crystal silicon substrate over which a driver circuit is formed by using a planar transistor illustrated in FIG. 9A may be bonded. Alternatively, a single crystal silicon substrate over which a driver circuit is formed using a fin-type transistor may be bonded.

Alternatively, as illustrated in FIG. 9B, a transistor including a semiconductor layer 545 of a silicon thin film may be used. The semiconductor layer 545 can be single crystal silicon (SOI (Silicon on Insulator)) formed over an insulating layer 546 over a silicon substrate 211, for example.

### Structure Example of OS Transistor

Alternatively, a single crystal silicon substrate over which a driving circuit is formed by providing an OS transistor may be bonded.

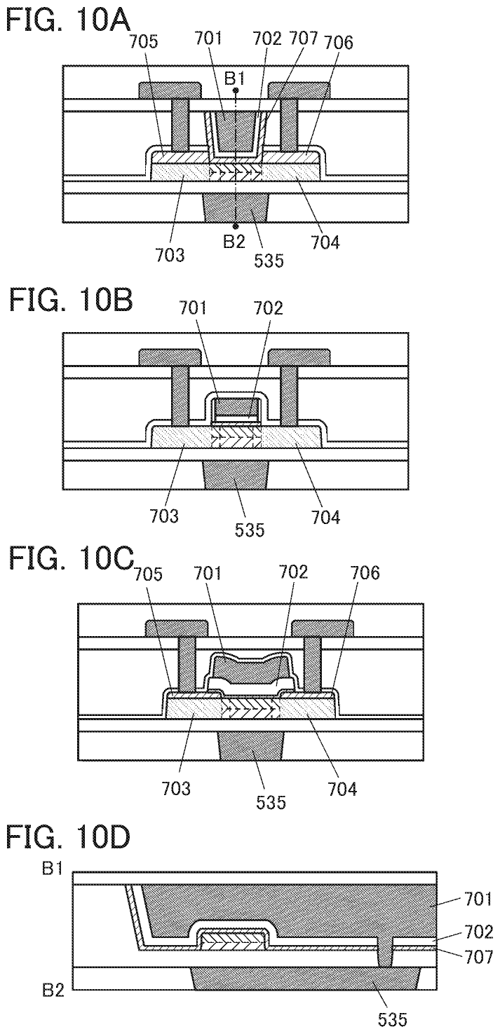

The details of an OS transistor are illustrated in FIG. 10A. The OS transistor illustrated in FIG. 10A has a self-aligned structure in which a source electrode 705 and a drain electrode 706 are formed through provision of an insulating layer over a stack of an oxide semiconductor layer and a conductive layer and provision of an opening portion reaching the oxide semiconductor layer.

The OS transistor can include a gate electrode 701 and a gate insulating film 702 in addition to a channel formation region, a source region 703, and a drain region 704 which are formed in the oxide semiconductor layer. At least the gate insulating film 702 and the gate electrode 701 are provided in the opening portion. An oxide semiconductor layer 707 may also be provided in the opening portion.

As illustrated in FIG. 10B, the OS transistor may have a self-aligned structure in which the source region 703 and the drain region 704 are formed in a semiconductor layer with the gate electrode 701 as a mask.

Alternatively, as illustrated in FIG. 10C, the OS transistor may be a non-self-aligned top-gate transistor including a region where the gate electrode 701 overlaps with the source electrode 705 or the drain electrode 706.

Although a structure in which the OS transistor includes a back gate 535 is illustrated, a structure without a back gate may be employed. As illustrated in a cross-sectional view of a transistor in a channel width direction in FIG. 10D, the back gate 535 may be electrically connected to a front gate of the transistor that is provided to face the back gate 535. Note that FIG. 10D illustrates an example of a B1-B2 cross section shown in FIG. 10A, and the same applies to transistors having other structures. Alternatively, a structure where a fixed potential different from the potential supplied to the front gate can be supplied to the back gate 535 may be employed.

As a semiconductor material used for an OS transistor, a metal oxide whose energy gap is greater than or equal to 2 eV, preferably greater than or equal to 2.5 eV, further preferably greater than or equal to 3 eV can be used. A typical example is an oxide semiconductor containing indium, and a CAAC-OS, a CAC-OS, or the like described later can be used, for example. A CAAC-OS has a crystal structure including stable atoms and is suitable for a transistor or the like that puts emphasis on reliability. In addition, a CAC-OS exhibits excellent mobility characteristics and thus is suitable for a transistor or the like that is driven at high speed.

In an OS transistor, a semiconductor layer has a large energy gap, and thus the OS transistor exhibits extremely low off-state current characteristics of several yoctoamperes per micrometer (the value of current per micrometer of channel width). In addition, an OS transistor has features such that impact ionization, an avalanche breakdown, a short-channel effect, and the like do not occur, which are different from those of a Si transistor, and enables formation of a circuit having high breakdown voltage and high reliability. Moreover, variations in electrical characteristics due to crystallinity unevenness, which are caused in Si transistors, are less likely to occur in OS transistors.

A semiconductor layer included in an OS transistor can be, for example, a film represented by an In-M-Zn-based oxide that contains indium, zinc, and M (one or more of metals such as aluminum, titanium, gallium, germanium, yttrium, zirconium, lanthanum, cerium, tin, neodymium, and hafnium). The In-M-Zn-based oxide can be typically formed by a sputtering method. Alternatively, the In-M-Zn-based oxide may be formed by an ALD (Atomic layer deposition) method.

It is preferable that the atomic ratio of metal elements in a sputtering target used to form an In-M-Zn oxide by a sputtering method satisfy In≥M and Zn≥M. The atomic ratio of metal elements of such a sputtering target is preferably In:M:Zn=1:1:1, In:M:Zn=1:1:1.2, In:M:Zn=3:1:2, In:M:Zn=4:2:3, In:M:Zn=4:2:4.1, In:M:Zn=5:1:6, In:M:Zn=5:1:7, In:M:Zn=5:1:8, or the like. Note that the atomic ratio in the deposited semiconductor layer varies from the atomic ratio of metal elements contained in the sputtering target in a range of +40%.

An oxide semiconductor with low carrier density is used for the semiconductor layer. For example, for the semiconductor layer, an oxide semiconductor whose carrier density is lower than or equal to 1×10¹⁷/cm³, preferably lower than or equal to 1×10¹⁵/cm³, further preferably lower than or equal to 1×10¹³/cm³, still further preferably lower than or equal to 1×10¹¹/cm³, even further preferably lower than 1×10¹⁰/cm³, and higher than or equal to 1×10⁻⁹/cm³ can be used. Such an oxide semiconductor is referred to as a highly purified intrinsic or substantially highly purified intrinsic oxide semiconductor. The oxide semiconductor has low density of defect states and can be referred to as an oxide semiconductor having stable characteristics.

Note that the composition is not limited to those, and a material having appropriate composition may be used depending on required semiconductor characteristics and electrical characteristics of the transistor (field-effect mobility, threshold voltage, or the like). In addition, to obtain the required semiconductor characteristics of the transistor, it is preferable that the carrier density, impurity concentration, defect density, atomic ratio between a metal element and oxygen, interatomic distance, density, and the like of the semiconductor layer be set to be appropriate.

When silicon or carbon, which is one of Group 14 elements, is contained in the oxide semiconductor that constitutes the semiconductor layer, oxygen vacancies are increased, and the semiconductor layer becomes n-type. Thus, the concentration (concentration obtained by secondary ion mass spectrometry) of silicon or carbon in the semiconductor layer is set lower than or equal to 2×10¹⁸ atoms/cm³, preferably lower than or equal to 2×10¹⁷ atoms/cm³.

In addition, alkali metal and alkaline earth metal might generate carriers when bonded to an oxide semiconductor, in which case the off-state current of the transistor might be increased. Thus, the concentration (concentration obtained by secondary ion mass spectrometry) of alkali metal or alkaline earth metal in the semiconductor layer is set lower than or equal to 1×10¹⁸ atoms/cm³, preferably lower than or equal to 2×10¹⁶ atoms/cm³.

Furthermore, when nitrogen is contained in the oxide semiconductor that constitutes the semiconductor layer, electrons serving as carriers are generated and the carrier density is increased, so that the semiconductor layer easily becomes n-type. As a result, a transistor using an oxide semiconductor that contains nitrogen is likely to have normally-on characteristics. Therefore, the concentration (concentration obtained by secondary ion mass spectrometry) of nitrogen in the semiconductor layer is preferably set lower than or equal to 5×10¹⁸ atoms/cm³.

In addition, when hydrogen is contained in an oxide semiconductor included in the semiconductor layer, hydrogen reacts with oxygen bonded to a metal atom to be water, and thus sometimes causes an oxygen vacancy in the oxide semiconductor. When a channel formation region in the oxide semiconductor includes oxygen vacancies, the transistor sometimes has normally-on characteristics. Furthermore, in some cases, a defect that is an oxygen vacancy into which hydrogen enters functions as a donor and generates an electron serving as a carrier. In other cases, bonding of part of hydrogen to oxygen bonded to a metal atom generates electrons serving as carriers. Thus, a transistor using an oxide semiconductor that contains a large amount of hydrogen is likely to have normally-on characteristics.

A defect in which hydrogen has entered an oxygen vacancy can function as a donor of the oxide semiconductor. However, it is difficult to evaluate the defect quantitatively. Thus, the oxide semiconductor is sometimes evaluated by not its donor concentration but its carrier concentration. Therefore, in this specification and the like, the carrier concentration assuming the state where an electric field is not applied is sometimes used, instead of the donor concentration, as the parameter of the oxide semiconductor. That is, “carrier concentration” described in this specification and the like can be replaced with “donor concentration” in some cases.

Therefore, hydrogen in the oxide semiconductor is preferably reduced as much as possible. Specifically, the hydrogen concentration in the oxide semiconductor that is obtained by secondary ion mass spectrometry (SIMS) is set lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³. When an oxide semiconductor with a sufficiently low concentration of impurities such as hydrogen is used for a channel formation region of a transistor, the transistor can have stable electrical characteristics.

Moreover, the semiconductor layer may have a non-single-crystal structure, for example. The non-single-crystal structure includes, for example, a CAAC-OS (C-Axis Aligned Crystalline Oxide Semiconductor) including a c-axis aligned crystal, a polycrystalline structure, a microcrystalline structure, or an amorphous structure. Among the non-single-crystal structures, the amorphous structure has the highest density of defect states, whereas the CAAC-OS has the lowest density of defect states.

An oxide semiconductor film having an amorphous structure has disordered atomic arrangement and no crystalline component, for example. Alternatively, an oxide semiconductor film having an amorphous structure has a completely amorphous structure and no crystal part, for example.

Note that the semiconductor layer may be a mixed film including two or more kinds selected from a region having an amorphous structure, a region having a microcrystalline structure, a region having a polycrystalline structure, a CAAC-OS region, and a region having a single crystal structure. The mixed film has, for example, a single-layer structure or a stacked-layer structure including two or more kinds of regions selected from the above regions in some cases.

The composition of a CAC (Cloud-Aligned Composite)-OS, which is one embodiment of a non-single-crystal semiconductor layer, is described below.

The CAC-OS is, for example, a composition of a material in which elements that constitute an oxide semiconductor are unevenly distributed to have a size of greater than or equal to 0.5 nm and less than or equal to 10 nm, preferably greater than or equal to 1 nm and less than or equal to 2 nm, or a similar size. Note that in the following description, a state in which one or more metal elements are unevenly distributed and regions including the metal element(s) are mixed to have a size of greater than or equal to 0.5 nm and less than or equal to 10 nm, preferably greater than or equal to 1 nm and less than or equal to 2 nm, or a similar size in an oxide semiconductor is referred to as a mosaic pattern or a patch-like pattern.

Note that the oxide semiconductor preferably contains at least indium. In particular, indium and zinc are preferably contained. Moreover, in addition to these, one kind or a plurality of kinds selected from aluminum, gallium, yttrium, copper, vanadium, beryllium, boron, silicon, titanium, iron, nickel, germanium, zirconium, molybdenum, lanthanum, cerium, neodymium, hafnium, tantalum, tungsten, magnesium, and the like may be contained.

For example, a CAC-OS in an In—Ga—Zn oxide (an In—Ga—Zn oxide in the CAC-OS may be particularly referred to as CAC-IGZO) has a composition in which materials are separated into indium oxide (hereinafter referred to as InO_{X1} (X1 is a real number greater than 0)) or indium zinc oxide (hereinafter referred to as In_{X2}Zn_{Y2}O_{Z2} (each of X2, Y2, and Z2 is a real number greater than 0)) and gallium oxide (hereinafter referred to as GaO_{X3} (X3 is a real number greater than 0)), or gallium zinc oxide (hereinafter referred to as Ga_{X4}Zn_{Y4}O_{Z4} (each of X4, Y4, and Z4 is a real number greater than 0)), and a mosaic pattern is formed, and mosaic-like InO_{X1} or In_{X2}Zn_{Y2}O_{Z2} is evenly distributed in the film (this composition is hereinafter also referred to as a cloud-like composition).

That is, the CAC-OS is a composite oxide semiconductor having a composition in which a region where GaO_{X3} is a main component and a region where In_{X2Z}n_{Y2}O_{Z2} or InO_{X1} is a main component are mixed. Note that in this specification, for example, when the atomic ratio of In to an element M in a first region is larger than the atomic ratio of In to the element M in a second region, the first region is regarded as having a higher In concentration than the second region.

Note that IGZO is a commonly known name and sometimes refers to one compound formed of In, Ga, Zn, and O. A typical example is a crystalline compound represented by InGaO₃(ZnO)ₘ₁ (m1 is a natural number) or In₍₁₊ₓ₀₎Ga₍₁₋ₓ₀₎O₃(ZnO)ₘ₀ (−1≤x0≤1; m0 is a given number).

The above-described crystalline compound has a single crystal structure, a polycrystalline structure, or a CAAC structure. Note that the CAAC structure is a crystal structure in which a plurality of IGZO nanocrystals have c-axis alignment and are connected in an a-b plane without alignment.

Meanwhile, the CAC-OS relates to the material composition of an oxide semiconductor. In the material composition of a CAC-OS containing In, Ga, Zn, and O, some regions that contain Ga as a main component and are observed as nanoparticles and some regions that contain In as a main component and are observed as nanoparticles are each randomly dispersed in a mosaic pattern. Therefore, the crystal structure is a secondary element for the CAC-OS.

Note that the CAC-OS is regarded as not including a stacked-layer structure of two or more kinds of films with different compositions. For example, a two-layer structure of a film containing In as a main component and a film containing Ga as a main component is not included.

Note that a clear boundary between the region where GaO_{X3} is a main component and the region where In_{X2}Zn_{Y2}O_{Z2} or InO_{X1} is a main component cannot be observed in some cases.

Note that in the case where one kind or a plurality of kinds selected from aluminum, yttrium, copper, vanadium, beryllium, boron, silicon, titanium, iron, nickel, germanium, zirconium, molybdenum, lanthanum, cerium, neodymium, hafnium, tantalum, tungsten, magnesium, and the like are contained instead of gallium, the CAC-OS refers to a composition in which some regions that contain the metal element(s) as a main component and are observed as nanoparticles and some regions that contain In as a main component and are observed as nanoparticles are each randomly dispersed in a mosaic pattern.

The CAC-OS can be formed by a sputtering method under a condition where a substrate is not heated intentionally, for example. In addition, in the case of forming the CAC-OS by a sputtering method, one or more selected from an inert gas (typically, argon), an oxygen gas, and a nitrogen gas may be used as a deposition gas. Furthermore, the ratio of the flow rate of an oxygen gas to the total flow rate of the deposition gas at the time of deposition is preferably as low as possible, and for example, the ratio of the flow rate of the oxygen gas is preferably higher than or equal to 0% and lower than 30%, further preferably higher than or equal to 0% and lower than or equal to 10%.

The CAC-OS is characterized in that no clear peak is observed at the time of measurement using θ/2θ scan by an Out-of-plane method, which is one of the X-ray diffraction (XRD) measurement methods. That is, it is found from X-ray diffraction measurement that no alignment in an a-b plane direction and a c-axis direction is observed in a measured region.

In addition, in an electron diffraction pattern of the CAC-OS that is obtained by irradiation with an electron beam with a probe diameter of 1 nm (also referred to as a nanobeam electron beam), a ring-like high-luminance region (ring region) and a plurality of bright spots in the ring region are observed. It is therefore found from the electron diffraction pattern that the crystal structure of the CAC-OS includes an nc (nano-crystal) structure with no alignment in a plan-view direction and a cross-sectional direction.

Moreover, for example, it can be confirmed by EDX mapping obtained using energy dispersive X-ray spectroscopy (EDX) that the CAC-OS in the In—Ga—Zn oxide has a composition in which regions where GaO_{X3} is a main component and regions where In_{X2}Zn_{Y2}O_{Z2} or InO_{X1} is a main component are unevenly distributed and mixed.

The CAC-OS has a composition different from that of an IGZO compound in which metal elements are evenly distributed, and has characteristics different from those of the IGZO compound. That is, the CAC-OS has a composition in which regions where GaO_{X3} or the like is a main component and regions where In_{X2}Zn_{Y2}O_{Z2} or InO_{X1} is a main component are phase-separated from each other, and the regions including the respective elements as the main components form a mosaic pattern.

Here, a region where In_{X2}Zn_{Y2}O_{Z2} or InO_{X1} is a main component is a region whose conductivity is higher than that of a region where GaO_{X3} or the like is a main component. In other words, when carriers flow through regions where In_{X2}Zn_{Y2}O_{Z2} or InO_{X1} is a main component, the conductivity of an oxide semiconductor is exhibited. Accordingly, when the regions where In_{X2}Zn_{Y2}O_{Z2} or InO_{X1} is a main component are distributed like a cloud in an oxide semiconductor, high field-effect mobility (μ) can be achieved.

In contrast, a region where GaO_{X3} or the like is a main component is a region whose insulating property is higher than that of a region where In_{X2}Zn_{Y2}O_{Z2} or InO_{X1} is a main component. In other words, when regions where GaO_{X3} or the like is a main component are distributed in an oxide semiconductor, leakage current can be suppressed and favorable switching operation can be achieved.

Accordingly, when the CAC-OS is used for a semiconductor element, the insulating property derived from GaO_{X3} or the like and the conductivity derived from In_{X2}Zn_{Y2}O_{Z2} or InO_{X1} complement each other, so that high on-state current (Iₒₙ) and high field-effect mobility (μ) can be achieved.

In addition, a semiconductor device using the CAC-OS has high reliability. Thus, the CAC-OS is suitable for a constituent material of a variety of semiconductor devices.

Note that as a conductor that can be used for a wiring, an electrode, and a plug used for electrical connection between devices, a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing the above metal element as its component; an alloy containing a combination of the above metal elements; or the like is selected and used as appropriate. The conductor is not limited to a single layer, and may be a plurality of layers including different materials.

A plurality of light-emitting diodes are arranged in a row direction or a column direction, and the single crystal silicon substrate 71S is separated along compartments so as to form a display region, whereby the display panel can be fabricated. Note that the size of the display panel using a single crystal silicon substrate is smaller than the size of the single crystal silicon substrate; therefore, the display panel using a single crystal silicon substrate is limited to a small display panel. Furthermore, when the interval between adjacent display regions is narrowed and small display panels are arranged in a row direction or a column direction, a large display panel can be achieved.

At least part of this embodiment can be implemented in appropriate combination with the other embodiments described in this specification.

### Embodiment 5

This embodiment shows an example in which an organic photodiode containing an organic compound in a photoelectric conversion layer is used for the light-receiving element 212. An organic photodiode is easily made thin and lightweight and easily has a large area. In addition, an organic photodiode can be used in a variety of display apparatuses because of its high flexibility in shape and design.

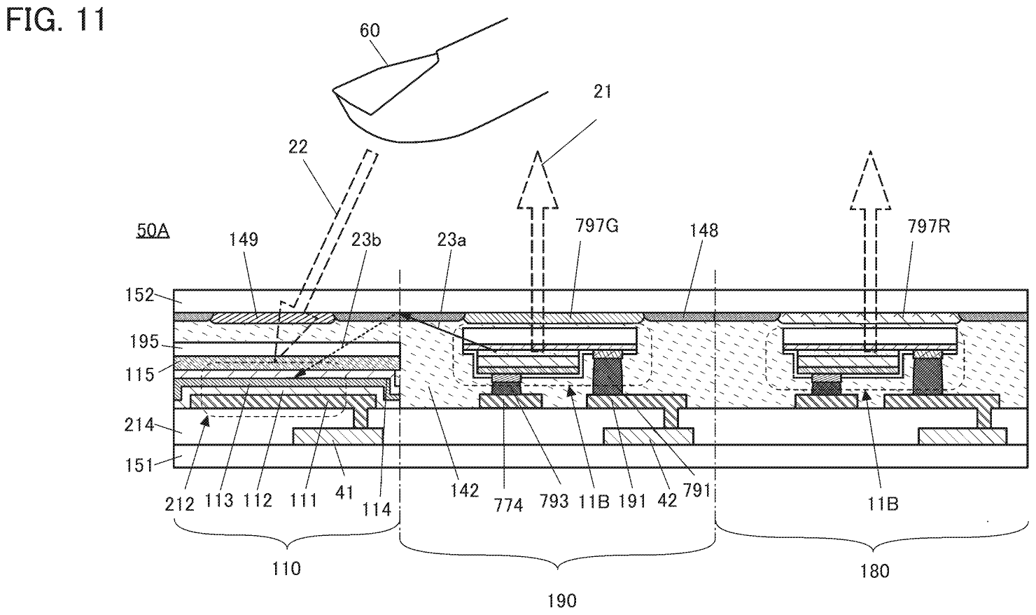

FIG. 11 is a cross-sectional schematic view of a display apparatus 50A of one embodiment of the present invention. The display apparatus 50A includes a light-receiving region 110, a light-emitting region 190, and a light-emitting region 180. The light-emitting region 190 includes a color conversion layer 797G and a light-emitting diode included in the blue the light-emitting diode 11B. The light-emitting region 180 corresponds to the color conversion layer 797G and a light-emitting diode (emitting green light) included in the blue the light-emitting diode 11B.

The light-emitting region 190, the light-emitting region 180, and their surroundings can have the same the structure except for the color conversion layer. Therefore, the light-emitting region 190 will be described in detail here, and description of the light-emitting region 180 will be omitted.

The light-emitting region 190 includes a terminal electrode 191, a conductive layer 774, a conductive bump 791, and a bump 793. In the display apparatus 50A illustrated in FIG. 11, the heights of the bump 791 and the bump 793 are different from each other. Note that in the case where the cathode-side electrode and the anode-side electrode of the blue the light-emitting diode 11B have the same height, the bump 791 and the bump 793 can have substantially the same height.

The light-receiving region 110 includes a pixel electrode 111, a common layer 112, a photoelectric conversion layer 113, a common layer 114, and a common electrode 115.

The pixel electrode 111, the terminal electrode 191, the common layer 112, the photoelectric conversion layer 113, the common layer 114, and the common electrode 115 may each have a single-layer structure or a stacked-layer structure.

The pixel electrode 111, the terminal electrode 191, and the conductive layer 774 are positioned over an insulating layer 214. The pixel electrode 111, the terminal electrode 191, and the conductive layer 774 can be formed using the same material in the same step.

The common layer 112 is positioned over the pixel electrode 111. The common layer 112 is a layer used in common in the light-receiving element 212 arranged in each pixel.

The photoelectric conversion layer 113 includes a region overlapping with the pixel electrode 111 with the common layer 112 therebetween. The photoelectric conversion layer 113 includes a first organic compound.

The common layer 114 is positioned over the common layer 112 and the photoelectric conversion layer 113. The common layer 114 is a layer used in common in the light-receiving element 212 arranged in each pixel.

The common electrode 115 includes a region overlapping with the pixel electrode 111 with the common layer 112, the photoelectric conversion layer 113, and the common layer 114 therebetween. The common electrode 115 is a layer used in common in the light-receiving element 212 arranged in each pixel.

In the display apparatus of this embodiment, an organic compound is used for the photoelectric conversion layer 113 of the light-receiving element 212. The light-emitting region 190 and the light-receiving region 110 can be formed over the same substrate. Thus, the light-receiving region 110 can be incorporated in the display apparatus.

The display apparatus 50A includes the light-receiving region 110, the light-emitting region 190, a transistor 41, a transistor 42, and the like between a pair of substrates (a substrate 151 having an insulating property and a substrate 152 having an insulating property).

As the substrate 151 having an insulating property and the substrate 152 having an insulating property, a glass substrate, a quartz substrate, or a plastic film can be used. For the plastic film, any of the following can be used: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber.

In the light-receiving region 110, the common layer 112, the photoelectric conversion layer 113, and the common layer 114 that are positioned between the pixel electrode 111 and the common electrode 115 can each be referred to as an organic layer (a layer containing an organic compound). The pixel electrode 111 preferably has a function of reflecting near-infrared light. The common electrode 115 has a function of transmitting visible light and near-infrared light. The light-receiving element 212 has a function of detecting light. Specifically, the light-receiving element 212 is a photoelectric conversion element that converts incident light 22 into an electric signal.

A light-blocking layer 148 is provided on a surface of the substrate 152 on the substrate 151 side. The light-blocking layer 148 has opening portions in a position overlapping with the light-receiving region 110 and in a position overlapping with the light-emitting region 190. Providing the light-blocking layer 148 can control the range where the light-receiving region 110 detects light.

A material that blocks light emitted by the light-emitting diode 11B can be used for the light-blocking layer 148. The light-blocking layer 148 preferably absorbs visible light and near-infrared light. The light-blocking layer 148 can be formed using a metal material or a resin material containing pigment (e.g., carbon black) or dye, for example. The light-blocking layer 148 may have a stacked-layer structure of a red color filter, a green color filter, and a blue color filter.

In addition, a filter 149 that filters out light with wavelengths shorter than the wavelength of light (near-infrared light) (received by the light-receiving element 212) is preferably provided in the opening portion of the light-blocking layer 148 that is provided in the position overlapping with the light-receiving region 110. For example, a long pass filter that filters out light having shorter wavelengths than near-infrared light, a band pass filter that filters out at least wavelengths in the visible light region, or the like can be used as the filter 149. A resin film or the like containing pigment or a semiconductor film such as an amorphous silicon thin film can be used as the filter that filters out visible light. When the filter 149 is provided, visible light can be inhibited from entering the light-receiving element 212, so that near-infrared light can be sensed with less noise.

Note that the filter 149 may be stacked with the light-receiving element 212.

Alternatively, the filter 149 may have a lens shape. The lens-type filter 149 is a convex lens having a convex surface on the substrate 151 side. Note that the filter 149 may be positioned so that the convex surface is on the substrate 152 side. In the case where both the light-blocking layer 148 and the lens-type filter 149 are formed on the same surface of the substrate 152, their formation order is not limited.

Alternatively, a structure without the filter 149 may be employed. The filter 149 can be omitted in the case where the light receiving element 212 has features such that it has no sensitivity to visible light or has sufficiently higher sensitivity to near-infrared light than that to visible light. In this case, a lens having a shape similar to that of the lens filter 149 may be provided to overlap the light-receiving element 212. The lens may be formed using a material that transmits visible light.

Here, the light-receiving region 110 can sense the light 22 reflected by an object 60 such as a finger, of light 21 emitted by the light-emitting diode 11B as illustrated in FIG. 11. However, in some cases, part of the light emitted by the light-emitting diode 11B is reflected inside the display apparatus 50A and enters the light-receiving region 110 without via the object 60.

The light-blocking layer 148 can reduce the influence of such stray light. For example, in the case where the light-blocking layer 148 is not provided, light 23a emitted by the light-emitting diode 11B is reflected by the substrate 152 or the like and reflected light 23b enters the light-receiving region 110 in some cases. Providing the light-blocking layer 148 can inhibit entry of the reflected light 23b into the light-receiving element 212. Hence, noise can be reduced, and the accuracy of sensing light of the light-receiving element 212 can be increased.

The light-emitting region 190 has a function of emitting green light. Specifically, the light-emitting diode 11B is an electroluminescent device in which when a voltage is applied between the terminal electrode 191 and the conductive layer 774, blue light is emitted to the substrate 152 side and passes through the color conversion layer 797G, so that green light 21 is emitted.

In the light-emitting region 190, the color conversion layer 797G is provided on the side of the substrate 152 that faces the substrate 151 at a position overlapping with the light-emitting diode 11B. In the light-emitting region 180, a color conversion layer 797R is provided on the side of the substrate 152 that faces the substrate 151 at a position overlapping with the light-emitting diode 11B.

Although this embodiment shows an example in which the blue light-emitting diode 11B is used, there is no particular limitation. In the case where the three kinds of light-emitting diodes 11R, 11B, and 11G are used, a color conversion layer is not necessarily provided. In addition, a light-emitting diode emitting ultraviolet light can be used instead of the light-emitting diode 11B. In the case where a light-emitting diode emitting ultraviolet light is used, a stacked-layer structure of a coloring layer and a color conversion layer which can perform color conversion to white light may be employed. The ultraviolet light passing through the color conversion layer is emitted as white light and the ultraviolet light passing through the coloring layer transmitting red light is emitted as red right to the display side.

At least part of circuits electrically connected to the light-receiving element 212 is preferably formed using the same material and the same step as a circuit which is electrically connected to the light-emitting diode 11B. In that case, the thickness of the display apparatus can be reduced compared with the case where the two circuits are separately formed, resulting in simplification of the manufacturing processes.

The light-receiving element 212 is preferably covered with a protective layer 195. The protective layer 195 and the substrate 152 are bonded to each other with an adhesive layer 142. The adhesive layer 142 is preferably formed using a material having a high light-transmitting property in order to transmit emitted light.

A gap between the adjacent light-emitting diodes 11B is filled with the adhesive layer 142 and the substrate 152 and the substrate 151 are bonded to each other.

Alternatively, a structure without the light-blocking layer 148 may be employed.

As the substrate 152, an optical member such as a scattering plate, an input device such as a touch sensor panel, or a structure in which two or more of the above are stacked may be employed.

The pixel electrode 111 is electrically connected to a source or a drain included in the transistor 41 through an opening provided in the insulating layer 214.

The terminal electrode 191 is electrically connected to a source or a drain included in the transistor 42 through an opening provided in the insulating layer 214. The transistor 42 has a function of controlling the driving of the light-emitting diode 11B.

The transistor 41 and the transistor 42 are provided over the same layer (the substrate 151 in FIG. 11).

### Structure Example of Transistor

Cross-sectional structure examples of the transistor 41 and the transistor 42 that can be used in the above described the display apparatus 50A are described below.

### Structure Example 1

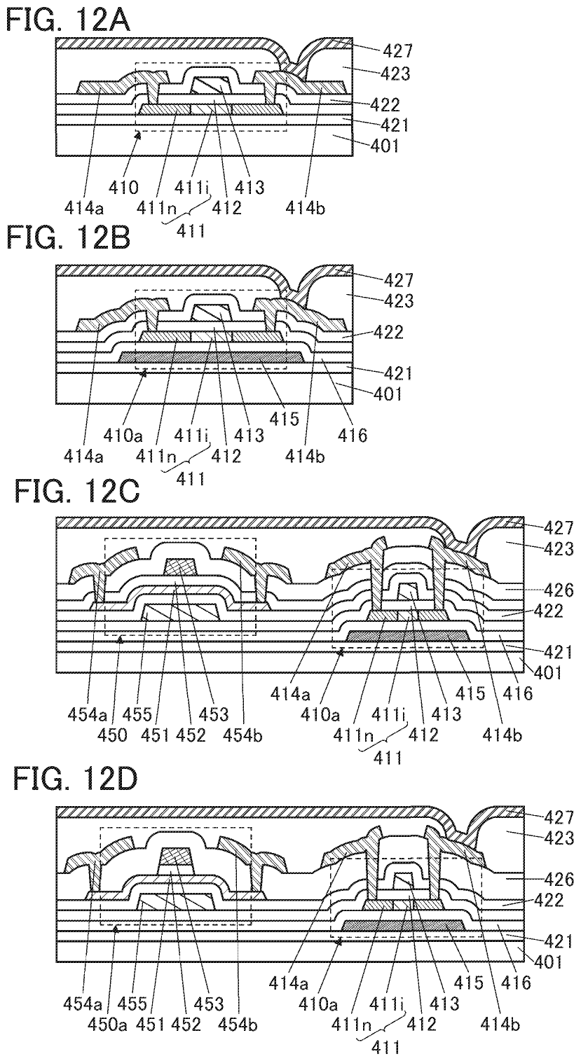

FIG. 12A is a cross-sectional view including a transistor 410.

The transistor 410 is a transistor provided over a substrate 401 and containing polycrystalline silicon in its semiconductor layer. For example, the transistor 410 corresponds to the transistor 42. The transistor 42 corresponds to the transistor 251 in the circuit in FIG. 6A. In other words, FIG. 12A illustrates an example in which one of a source and a drain of the transistor 410 is electrically connected to a light-emitting diode. Note that a transistor containing low-temperature polysilicon (LTPS) (hereinafter, also referred to as an “LTPS transistor”) can be used as one of transistors including polycrystalline silicon in its semiconductor layer. The LTPS transistor has high field-effect mobility and favorable frequency characteristics.

The transistor 410 includes a semiconductor layer 411, an insulating layer 412, a conductive layer 413, and the like. The semiconductor layer 411 includes a channel formation region 411i and low-resistance regions 411n. The semiconductor layer 411 contains silicon. The semiconductor layer 411 preferably contains polycrystalline silicon. Part of the insulating layer 412 functions as a gate insulating layer. Part of the conductive layer 413 functions as a gate electrode.

Note that the semiconductor layer 411 can include a metal oxide exhibiting semiconductor characteristics (also referred to as an oxide semiconductor). In this case, the transistor 410 can be referred to as an OS transistor.

The low-resistance regions 411n are each a region containing an impurity element. For example, in the case where the transistor 410 is an n-channel transistor, phosphorus, arsenic, or the like is added to the low-resistance regions 411n. Meanwhile, in the case where the transistor 410 is a p-channel transistor, boron, aluminum, or the like is added to the low-resistance regions 411n. In addition, in order to control the threshold voltage of the transistor 410, the above-described impurity may be added to the channel formation region 411i.

An insulating layer 421 is provided over the substrate 401. The semiconductor layer 411 is provided over the insulating layer 421. The insulating layer 412 is provided to cover the semiconductor layer 411 and the insulating layer 421. The conductive layer 413 is provided at a position being over the insulating layer 412 and overlapping with the semiconductor layer 411.

An insulating layer 422 is provided to cover the conductive layer 413 and the insulating layer 412. A conductive layer 414a and a conductive layer 414b are provided over the insulating layer 422. The conductive layer 414a and the conductive layer 414b are electrically connected to the low-resistance regions 411n in opening portions provided in the insulating layer 422 and the insulating layer 412. Part of the conductive layer 414a functions as one of a source electrode and a drain electrode and part of the conductive layer 414b functions as the other of the source electrode and the drain electrode. An insulating layer 423 is provided to cover the conductive layer 414a, the conductive layer 414b, and the insulating layer 422.

A conductive layer 427 functioning as a pixel electrode is provided over the insulating layer 423. The conductive layer 427 is provided over the insulating layer 423 and is electrically connected to the conductive layer 414b through an opening provided in the insulating layer 423. Although not illustrated here, the conductive layer 427 is electrically connected to an electrode of an LED over the conductive layer 427, whereby the LED can be mounted over the driver circuit.

### Structure Example 2

FIG. 12B illustrates a transistor 410a including a pair of gate electrodes. The transistor 410a illustrated in FIG. 12B is different from that illustrated in FIG. 12A mainly in including a conductive layer 415 and an insulating layer 416.

The conductive layer 415 is provided over the insulating layer 421. The insulating layer 416 is provided to cover the conductive layer 415 and the insulating layer 421. The semiconductor layer 411 is provided such that at least the channel formation region 411i overlaps with the conductive layer 415 with the insulating layer 416 therebetween.

In the transistor 410a illustrated in FIG. 12B, part of the conductive layer 413 functions as a first gate electrode, and part of the conductive layer 415 functions as a second gate electrode. At this time, part of the insulating layer 412 functions as a first gate insulating layer, and part of the insulating layer 416 functions as a second gate insulating layer.

Here, to electrically connect the first gate electrode to the second gate electrode, the conductive layer 413 is electrically connected to the conductive layer 415 through an opening portion provided in the insulating layer 412 and the insulating layer 416 in a region not illustrated. To electrically connect the second gate electrode to a source or a drain, the conductive layer 415 is electrically connected to the conductive layer 414a or the conductive layer 414b through an opening portion provided in the insulating layer 422, the insulating layer 412, and the insulating layer 416 in a region not illustrated.

In the case where LTPS transistors are used as all of the transistors included in the pixel, the transistor 410 illustrated in FIG. 12A as an example or the transistor 410a illustrated in FIG. 12B as an example can be used. In this case, the transistors 410a may be used as all of the transistors included in the pixels, the transistors 410 may be used as all of the transistors, or the transistors 410a and the transistors 410 may be used in combination.

### Structure Example 3

Described below is an example of a structure including both a transistor containing silicon in its semiconductor layer and a transistor containing a metal oxide in its semiconductor layer.

FIG. 12C is a schematic cross-sectional view including the transistor 410a and a transistor 450.

Structure example 2 described above can be referred to for the transistor 410a. Although an example using the transistor 410a is illustrated here, a structure including the transistor 410 and the transistor 450 or a structure including all the transistor 410, the transistor 410a, and the transistor 450 may alternatively be employed.

The transistor 450 is a transistor including a metal oxide in its semiconductor layer. The structure in FIG. 12C illustrates an example in which the transistor 450 and the transistor 410a correspond to the transistor 436 and the transistor 251, respectively, in the circuit in FIG. 6A. That is, FIG. 12C illustrates an example in which one of the source and the drain of the transistor 410a is electrically connected to the conductive layer 427 which is electrically connected to the electrode of the LED.

Moreover, FIG. 12C illustrates an example in which the transistor 450 includes a pair of gates.

The transistor 450 includes a conductive layer 455, the insulating layer 422, a semiconductor layer 451, an insulating layer 452, a conductive layer 453, and the like. Part of the conductive layer 453 functions as a first gate of the transistor 450, and part of the conductive layer 455 functions as a second gate of the transistor 450. In this case, part of the insulating layer 452 functions as a first gate insulating layer of the transistor 450, and part of the insulating layer 422 functions as a second gate insulating layer of the transistor 450.

The conductive layer 455 is provided over the insulating layer 412. The insulating layer 422 is provided to cover the conductive layer 455. The semiconductor layer 451 is provided over the insulating layer 422. The insulating layer 452 is provided to cover the semiconductor layer 451 and the insulating layer 422. The conductive layer 453 is provided over the insulating layer 452 and includes a region overlapping with the semiconductor layer 451 and the conductive layer 455.

An insulating layer 426 is provided to cover the insulating layer 452 and the conductive layer 453. A conductive layer 454a and a conductive layer 454b are provided over the insulating layer 426. The conductive layer 454a and the conductive layer 454b are electrically connected to the semiconductor layer 451 in opening portions provided in the insulating layer 426 and the insulating layer 452. Part of the conductive layer 454a functions as one of a source electrode and a drain electrode and part of the conductive layer 454b functions as the other of the source electrode and the drain electrode. The insulating layer 423 is provided to cover the conductive layer 454a, the conductive layer 454b, and the insulating layer 426.

Here, the conductive layer 414a and the conductive layer 414b that are electrically connected to the transistor 410a are preferably formed by processing the same conductive film as the conductive layer 454a and the conductive layer 454b. FIG. 12C illustrates a structure in which the conductive layer 414a, the conductive layer 414b, the conductive layer 454a, and the conductive layer 454b are formed on the same plane (i.e., in contact with the top surface of the insulating layer 426) and contain the same metal element. In this case, the conductive layer 414a and the conductive layer 414b are electrically connected to the low-resistance regions 411n through openings provided in the insulating layer 426, the insulating layer 452, the insulating layer 422, and the insulating layer 412. This is preferable because the manufacturing process can be simplified.

Moreover, the conductive layer 413 functioning as the first gate electrode of the transistor 410a and the conductive layer 455 functioning as the second gate electrode of the transistor 450 are preferably formed by processing the same conductive film. FIG. 12C illustrates a structure in which the conductive layer 413 and the conductive layer 455 are formed on the same plane (i.e., in contact with the top surface of the insulating layer 412) and contain the same metal element. This is preferable because the manufacturing process can be simplified.

In the structure in FIG. 12C, the insulating layer 452 functioning as the first gate insulating layer of the transistor 450 covers an end portion of the semiconductor layer 451; however, the insulating layer 452 may be processed to have the same or substantially the same top surface shape as the conductive layer 453 as in a transistor 450a illustrated in FIG. 12D.

As illustrated in FIG. 12C and FIG. 12D, a semiconductor device with low power consumption and high drive capability can be achieved with the structure which includes both of a transistor containing silicon in its semiconductor layer and a transistor containing a metal oxide in its semiconductor layer. Furthermore, a structure in which an LTPS transistor and an OS transistor are combined is referred to as LTPO in some cases. Note that as a more preferable example, it is preferable to use an OS transistor as, for example, a transistor functioning as a switch for controlling electrical continuity between wirings and an LTPS transistor as, for example, a transistor for controlling current.

Note that in this specification and the like, the expression “top surface shapes are substantially the same” means that at least outlines of stacked layers partly overlap with each other. For example, the case of processing the upper layer and the lower layer with the use of the same mask pattern or mask patterns that are partly the same is included. However, in some cases, the outlines do not completely overlap with each other and the upper layer is positioned inward from the lower layer or the upper layer is positioned outward from the lower layer; such cases are also represented by the expression “top surface shapes are substantially the same”.

Although the example in which the transistor 410a corresponds to the transistor 251 and is electrically connected to the pixel electrode is shown here, one embodiment of the present invention is not limited thereto. For example, a structure in which the transistor 450 or the transistor 450a corresponds to the transistor 251 may be employed. In that case, the transistor 410a corresponds to the transistor 436, the transistor 434, or another transistor.

At least part of this embodiment can be implemented in appropriate combination with the other embodiments described in this specification.

### Embodiment 6

In this embodiment, electronic apparatuses that can include the semiconductor device of one embodiment of the present invention are described.

The semiconductor device of one embodiment of the present invention can be used in a display portion of an electronic apparatus. Thus, an electronic apparatus with high display quality can be obtained. An electronic apparatus with an extremely high resolution can be obtained. A highly reliable electronic apparatus can be obtained.

Examples of the electronic apparatuses including any of the semiconductor devices of one embodiment of the present invention are as follows: display apparatuses such as televisions and monitors, lighting devices, desktop or laptop personal computers, word processors, image reproduction devices which reproduce still images and moving images stored in recording media such as DVDs (Digital Versatile Discs), portable CD players, radios, tape recorders, headphone stereos, stereos, table clocks, wall clocks, cordless phone handsets, transceivers, car phones, mobile phones, portable information terminals, tablet terminals, portable game machines, stationary game machines such as pachinko machines, calculators, electronic notebooks, e-book readers, electronic translators, audio input devices, video cameras, digital still cameras, electric shavers, high-frequency heating appliances such as microwave ovens, electric rice cookers, electric washing machines, electric vacuum cleaners, water heaters, electric fans, hair dryers, air-conditioning systems such as air conditioners, humidifiers, and dehumidifiers, dishwashers, dish dryers, clothes dryers, futon dryers, electric refrigerators, electric freezers, electric refrigerator-freezers, freezers for preserving DNA, flashlights, electrical tools such as chain saws, smoke detectors, and medical equipment such as dialyzers. Other examples include industrial equipment such as guide lights, traffic lights, conveyor belts, elevators, escalators, industrial robots, power storage systems, and power storage devices for leveling the amount of power supply and smart grid. In addition, moving objects and the like driven by fuel engines or electric motors using power from power storage units may also be included in the category of electronic apparatus. Examples of the moving objects include electric vehicles (EV), hybrid electric vehicles (HV) which include both an internal-combustion engine and a motor, plug-in hybrid electric vehicles (PHV), tracked vehicles in which caterpillar tracks are substituted for wheels of these vehicles, motorized bicycles including motor-assisted bicycles, motorcycles, electric wheelchairs, golf carts, boats, ships, submarines, helicopters, aircraft, rockets, artificial satellites, space probes, planetary probes, and spacecraft.

The electronic apparatus of one embodiment of the present invention may include a secondary battery (battery), and it is preferable that the secondary battery be capable of being charged by contactless power transmission.

Examples of the secondary battery include a lithium ion secondary battery, a nickel-hydride battery, a nickel-cadmium battery, an organic radical battery, a lead-acid battery, an air secondary battery, a nickel-zinc battery, and a silver-zinc battery.

The electronic apparatus of one embodiment of the present invention may include an antenna. With the antenna receiving a signal, the electronic apparatus can display images, information, and the like on a display portion. When the electronic apparatus includes the antenna and a secondary battery, the antenna may be used for contactless power transmission.

The electronic apparatus of one embodiment of the present invention may include a sensor (a sensor having a function of measuring force, displacement, position, speed, acceleration, angular velocity, rotational frequency, distance, light, liquid, magnetism, temperature, a chemical substance, sound, time, hardness, an electric field, current, voltage, electric power, radioactive rays, flow rate, humidity, a gradient, oscillation, odor, or infrared rays).

The electronic apparatus of one embodiment of the present invention can have a variety of functions. For example, the electronic apparatus can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Furthermore, an electronic apparatus including a plurality of display portions can have a function of displaying image information mainly on one display portion while displaying text information mainly on another display portion, a function of displaying a three-dimensional image by displaying images on the plurality of display portions with a parallax taken into account, or the like. Furthermore, an electronic apparatus including an image receiving portion can have a function of taking a still image or a moving image, a function of automatically or manually correcting a taken image, a function of storing a taken image in a recording medium (an external recording medium or a recording medium incorporated in the electronic apparatus), a function of displaying a taken image on a display portion, or the like. Note that functions of the electronic apparatus of one embodiment of the present invention are not limited thereto, and the electronic apparatus can have a variety of functions.

The semiconductor device of one embodiment of the present invention can display a high-definition image. For this reason, the semiconductor device can be used especially for portable electronic apparatuses, wearable electronic apparatuses (wearable devices), e-book readers, and the like. In addition, the semiconductor device can be suitably used for xR devices such as a VR device and an AR device.

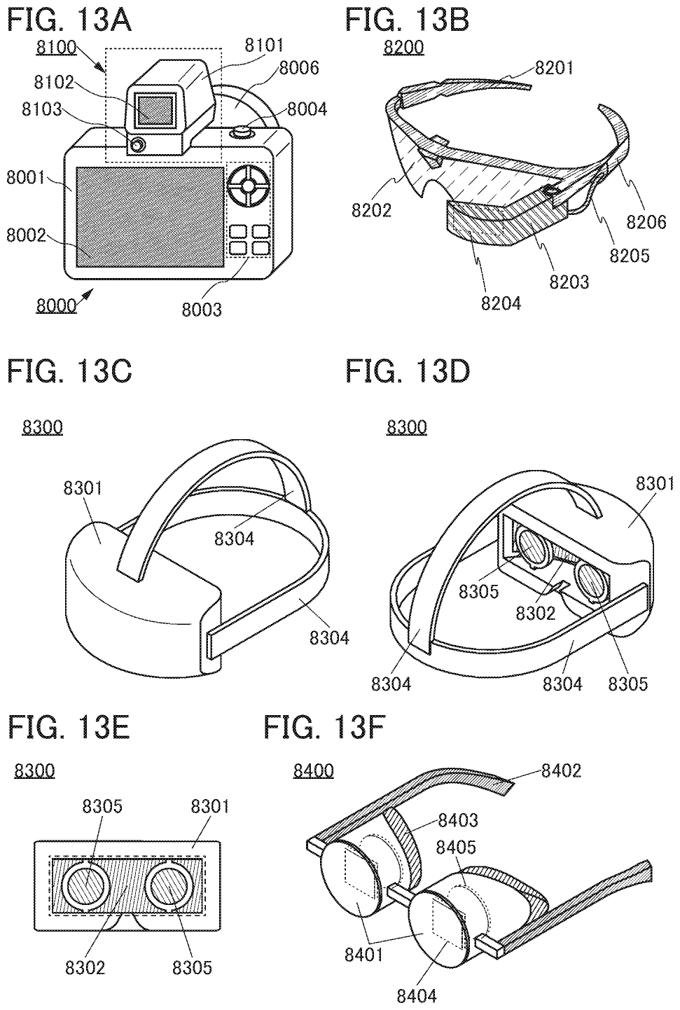

FIG. 13A is a diagram illustrating the appearance of a camera 8000 to which a finder 8100 is attached.

The camera 8000 includes a housing 8001, a display portion 8002, operation buttons 8003, a shutter button 8004, and the like. In addition, a detachable lens 8006 is attached to the camera 8000. Note that the lens 8006 and the housing may be integrated with each other in the camera 8000.

The camera 8000 can take images by the press of the shutter button 8004 or touch on the display portion 8002 serving as a touch panel.

The housing 8001 includes a mount including an electrode, so that the finder 8100, a stroboscope, or the like can be connected to the housing.

The finder 8100 includes a housing 8101, a display portion 8102, a button 8103, and the like.

The housing 8101 is attached to the camera 8000 with the mount engaging with a mount of the camera 8000. In the finder 8100, a video or the like received from the camera 8000 can be displayed on the display portion 8102.

The button 8103 functions as a power button or the like.

The semiconductor device of one embodiment of the present invention can be used in the display portion 8002 of the camera 8000 and the display portion 8102 of the finder 8100. Note that the finder 8100 may be incorporated in the camera 8000. The size of a display region of the display portion 8002 and the display portion 8102, that is, the screen size is greater than or equal to 0.5 inches and less than or equal to 10 inches.

FIG. 13B is a diagram illustrating the appearance of a head-mounted display 8200.

The head-mounted display 8200 includes a wearing portion 8201, a lens 8202, a main body 8203, a display portion 8204, a cable 8205, and the like. A battery 8206 is incorporated in the wearing portion 8201.

The cable 8205 supplies electric power from the battery 8206 to the main body 8203. The main body 8203 includes a wireless receiver or the like to receive video data and display it on the display portion 8204. The main body 8203 includes a camera, and data on the movement of eyeballs or eyelids of the user can be used as an input means.

The wearing portion 8201 may be provided with a plurality of electrodes capable of detecting current flowing in response to the movement of the user's eyeball in a position in contact with the user to have a function of recognizing the user's sight line. Furthermore, the wearing portion 8201 may have a function of monitoring the user's pulse with use of current flowing through the electrodes. The wearing portion 8201 may include a variety of sensors such as a temperature sensor, a pressure sensor, and an acceleration sensor to have a function of displaying the user's biological information on the display portion 8204, a function of changing a video displayed on the display portion 8204 in accordance with the movement of the user's head, and the like.

The semiconductor device of one embodiment of the present invention can be used in the display portion 8204. The size of the display region of the display portion 8204, i.e., the screen size is greater than or equal to 0.5 inches and less than or equal to 3 inches.

FIG. 13C to FIG. 13E are diagrams illustrating the appearance of a head-mounted display 8300. The head-mounted display 8300 includes a housing 8301, a display portion 8302, a fixing band 8304, and a pair of lenses 8305.

A user can see display on the display portion 8302 through the lenses 8305. Note that the display portion 8302 is preferably curved and placed because the user can feel a high realistic sensation. Another image displayed in another region of the display portion 8302 is viewed through the lenses 8305, so that three-dimensional display using parallax or the like can be performed. Note that the structure is not limited to the structure in which one display portion 8302 is provided; two display portions 8302 may be provided and one display portion may be provided per eye of the user.

The semiconductor device of one embodiment of the present invention can be used for the display portion 8302. The semiconductor device of one embodiment of the present invention can achieve extremely high definition. For example, a pixel is not easily perceived by the user even when the user perceives display that is magnified by the use of the lenses 8305 as illustrated in FIG. 13E. In other words, a video with a strong sense of reality can be seen by the user with the use of the display portion 8302.

FIG. 13F is a diagram illustrating the appearance of a goggle-type head-mounted display 8400. The head-mounted display 8400 includes a pair of housings 8401, a wearing portion 8402, and a cushion 8403. A display portion 8404 and a lens 8405 are provided in each of the pair of housings 8401. The pair of display portions 8404 may display different images, whereby three-dimensional display using parallax can be performed.

A user can see display on the display portion 8404 through the lens 8405. The lens 8405 has a focus adjustment mechanism and can adjust the position according to the user's eyesight. The display portion 8404 is preferably a square or a horizontal rectangle. This can improve a realistic sensation.

The wearing portion 8402 preferably has plasticity and elasticity to be adjusted to fit the size of the user's face and not to slide down. In addition, part of the wearing portion 8402 preferably has a vibration mechanism functioning as a bone conduction earphone. Thus, without additionally requiring an audio device such as earphones or a speaker, the user can enjoy video and sound only by wearing. Note that the housings 8401 may have a function of outputting sound data by wireless communication.

The wearing portion 8402 and the cushion 8403 are portions in contact with the user's face (forehead, cheek, or the like). The cushion 8403 is in close contact with the user's face, so that light leakage can be prevented, which increases the sense of immersion. The cushion 8403 is preferably formed using a soft material so that the head-mounted display 8400 is in close contact with the user's face when being worn by the user. For example, a material such as rubber, silicone rubber, urethane, or sponge can be used. Furthermore, when a sponge or the like whose surface is covered by cloth, leather (natural leather or synthetic leather), or the like is used, a gap is unlikely to be generated between the user's face and the cushion 8403, whereby light leakage can be suitably prevented. Furthermore, using such a material is preferable because it has a soft texture and the user does not feel cold when wearing the device in a cold season, for example. The member in contact with user's skin, such as the cushion 8403 or the wearing portion 8402, is preferably detachable because cleaning or replacement can be easily performed.

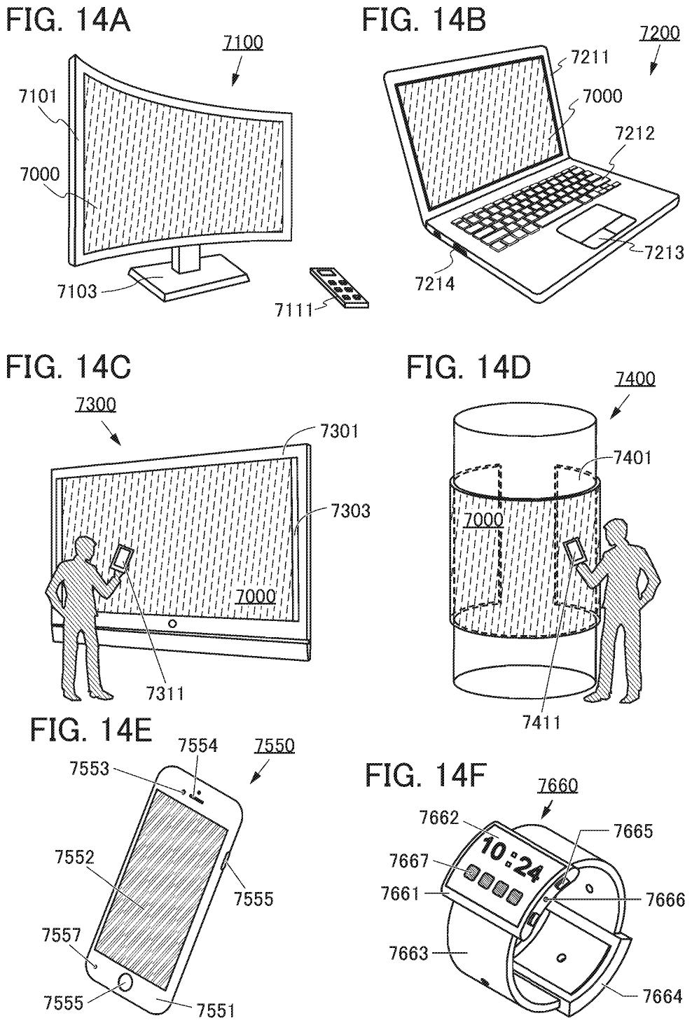

FIG. 14A illustrates an example of a television device. In a television device 7100, a display portion 7000 is incorporated in a housing 7101. Here, the housing 7101 is supported by a stand 7103.

The semiconductor device of one embodiment of the present invention can be used for the display portion 7000. The size of a display region of the display portion 8204, i.e., the screen size is greater than or equal to 8 inches and less than or equal to 100 inches.

Operation of the television device 7100 illustrated in FIG. 14A can be performed with an operation switch provided in the housing 7101 and a separate remote control 7111. Alternatively, the display portion 7000 may include a touch sensor, and the television device 7100 may be operated by touch on the display portion 7000 with a finger or the like. The remote control 7111 may be provided with a display portion for displaying information output from the remote control 7111. With operation keys or a touch panel provided in the remote control 7111, channels and volume can be operated and videos displayed on the display portion 7000 can be operated.

Note that the television device 7100 has a structure in which a receiver, a modem, and the like are provided. A general television broadcast can be received with the receiver. When the television device is connected to a communication network with or without wires via the modem, one-way (from a transmitter to a receiver) or two-way (between a transmitter and a receiver or between receivers, for example) data communication can be performed.

FIG. 14B illustrates an example of a laptop personal computer. A laptop personal computer 7200 includes a housing 7211, a keyboard 7212, a pointing device 7213, an external connection port 7214, and the like. In the housing 7211, the display portion 7000 is incorporated.

The semiconductor device of one embodiment of the present invention can be used for the display portion 7000.

FIGS. 14C and 14D illustrate examples of digital signage.

Digital signage 7300 illustrated in FIG. 14C includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 14D is digital signage 7400 attached to a cylindrical pillar 7401. The digital signage 7400 includes the display portion 7000 provided along a curved surface of the pillar 7401.

The semiconductor device of one embodiment of the present invention can be used for the display portion 7000 in FIG. 14C and FIG. 14D.

A larger area of the display portion 7000 can increase the amount of information that can be provided at a time. The larger the display portion 7000 attracts more attention, so that the effectiveness of the advertisement can be increased, for example.

The use of a touch panel in the display portion 7000 is preferable because in addition to display of an image or a moving image on the display portion 7000, intuitive operation by a user is possible. Moreover, for an application for providing information such as route information or traffic information, usability can be enhanced by intuitive operation.

As illustrated in FIG. 14C and FIG. 14D, it is preferable that the digital signage 7300 or the digital signage 7400 can work with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

An information terminal 7550 illustrated in FIG. 14E includes a housing 7551, a display portion 7552, a microphone 7557, a speaker portion 7554, a camera 7553, operation switches 7555, and the like. The semiconductor device of one embodiment of the present invention can be used for the display portion 7552. The display portion 7552 functions as a touch panel. The information terminal 7550 also includes an antenna, a battery, and the like inside the housing 7551. The information terminal 7550 can be used as, for example, a smartphone, a mobile phone, a tablet information terminal, a tablet personal computer, an e-book reader, or the like.

FIG. 14F illustrates an example of a watch-type information terminal. An information terminal 7660 includes a housing 7661, a display portion 7662, a band 7663, a buckle 7664, an operation switch 7665, an input/output terminal 7666, and the like. In addition, the information terminal 7660 includes an antenna, a battery, and the like inside the housing 7661. The information terminal 7660 is capable of executing a variety of applications such as mobile phone calls, e-mailing, text viewing and editing, music reproduction, Internet communication, and computer games.

In addition, the display portion 7662 includes a touch sensor, and operation can be performed by touching the screen with a finger, a stylus, or the like. For example, with a touch on an icon 7667 displayed on the display portion 7662, an application can be started. With the operation switch 7665, a variety of functions such as time setting, power on/off, on/off of wireless communication, setting and cancellation of a silent mode, and setting and cancellation of a power saving mode can be performed. For example, the functions of the operation switch 7665 can be set by the operating system incorporated in the information terminal 7660.

The information terminal 7660 can execute near field communication conformable to a communication standard. For example, mutual communication with a headset capable of wireless communication enables hands-free calling. The information terminal 7660 includes the input/output terminal 7666, and can perform data transmission and reception with another information terminal through the input/output terminal 7666. In addition, charging can be performed via the input/output terminal 7666. Note that the charging operation may be performed by wireless power feeding without using the input/output terminal 7666.

The structures described in this embodiment can be used in an appropriate combination with the structures described in the other embodiments and the like.

### REFERENCE NUMERALS

10: pixel, 11a: electrode, 11B: light-emitting diode, 11G: light-emitting diode, 11IR: light-emitting diode, 11R: light-emitting diode, 11UV: light-emitting diode, 11W: light-emitting diode, 13: driver circuit portion, 14: driver circuit portion, 15: circuit portion, 16: control circuit portion, 17: pixel array, 21: light, 22: light, 23a: light, 23b: reflected light, 41: transistor, 42: transistor, 50A: display apparatus, 51: LED chip, 60: object, 71: substrate, 71B: single crystal silicon substrate, 71G: single crystal silicon substrate, 71R: single crystal silicon substrate, 71S: single crystal silicon substrate, 75: n-type semiconductor layer, 75a: n-type contact layer, 75b: n-type clad layer, 77: light-emitting layer, 77a: barrier layer, 77b: well layer, 79: p-type semiconductor layer, 79a: p-type clad layer, 79b: p-type contact layer, 81: semiconductor layer, 82: light-receiving region, 83: electrode, 85: electrode, 87: electrode, 89: insulating layer, 102: transistor, 102_k: transistor, 102_1: transistor, 102_2: transistor, 103: transistor, 104: transistor, 105: transistor, 108: capacitor, 110: light-receiving region, 111: pixel electrode, 112: common layer, 113: photoelectric conversion layer, 114: common layer, 115: common electrode, 121: wiring, 122: wiring, 123: wiring, 126: wiring, 127: wiring, 127_k: wiring, 127_1: wiring, 127_2: wiring, 128: wiring, 131: wiring, 132: wiring, 133: wiring, 142: adhesive layer, 148: light-blocking layer, 149: filter, 151: substrate, 152: substrate, 180: light-emitting region, 190: light-emitting region, 191: terminal electrode, 193: light-emitting layer, 195: protective layer, 200: display panel, 200A: display panel, 200B: display panel, 200C: display panel, 201: glass substrate, 202: protective substrate, 202b: color conversion layer, 202g: color conversion layer, 202G: color conversion layer, 202r: color conversion layer, 202R: color conversion layer, 203: functional layer, 203a: terminal electrode, 211: silicon substrate, 212: light-receiving element, 212_k: light-receiving element, 212_1: light-receiving element, 212_2: light-receiving element, 214: insulating layer, 220: finger, 231: driver circuit portion, 232: driver circuit portion, 236: wiring, 237: wiring, 251: transistor, 352: wiring, 401: substrate, 410: transistor, 410a: transistor, 411: semiconductor layer, 411i: channel formation region, 411n: low-resistance region, 412: insulating layer, 413: conductive layer, 414a: conductive layer, 414b: conductive layer, 415: conductive layer, 416: insulating layer, 421: insulating layer, 422: insulating layer, 423: insulating layer, 426: insulating layer, 427: conductive layer, 431: display pixel circuit, 433: capacitor element, 434: transistor, 435: node, 436: transistor, 437: node, 438: transistor, 450: transistor, 450a: transistor, 451: semiconductor layer, 452: insulating layer, 453: conductive layer, 454a: conductive layer, 454b: conductive layer, 455: conductive layer, 535: back gate, 545: semiconductor layer, 546: insulating layer, 701: gate electrode, 702: gate insulating film, 703: source region, 704: drain region, 705: source electrode, 706: drain electrode, 707: oxide semiconductor layer, 774: conductive layer, 791: bump, 793: bump, 797G: color conversion layer, 797R: color conversion layer, 901: substrate, 902: substrate, 903: substrate, 904: single crystal silicon wafer, 7000: display portion, 7100: television device, 7101: housing, 7103: stand, 7111: remote control, 7200: laptop personal computer, 7211: housing, 7212: keyboard, 7213: pointing device, 7214: external connection port, 7300: digital signage, 7301: housing, 7303: a speaker, 7311: information terminal, 7400: digital signage, 7401: pillar, 7411: information terminal, 7550: information terminal, 7551: housing, 7552: display portion, 7553: camera, 7554: speaker portion, 7555: operation switch, 7557: microphone, 7660: information terminal, 7661: housing, 7662: display portion, 7663: band, 7664: a buckle, 7665: operation switch, 7666: input/output terminal, 7667: icon, 8000: camera, 8001: housing, 8002: display portion, 8003: operation button, 8004: shutter button, 8006: lens, 8100: finder, 8101: housing, 8102: display portion, 8103: button, 8200: head-mounted display, 8201: wearing portion, 8202: lens, 8203: main body, 8204: display portion, 8205: cable, 8206: battery, 8300: head-mounted display, 8301: housing, 8302: display portion, 8304: fixing band, 8305: lens, 8400: head-mounted display, 8401: housing, 8402: wearing portion, 8403: cushion, 8404: display portion, 8405: lens

1. A semiconductor device comprising:
a plurality of first terminal electrodes and a plurality of second terminal electrodes over a substrate;
a light-emitting diode over the first terminal electrode; and
a light-receiving element comprising a photoelectric conversion layer over the second terminal electrode,
wherein the light-emitting diode comprises a first electrode and a second electrode,
wherein the first electrode overlaps with the first terminal electrode,
wherein the first terminal electrode is electrically connected to a driver circuit of the light-emitting diode, and
wherein the second terminal electrode is electrically connected to a driver circuit of the light-receiving element.

2. The semiconductor device according to claim 1,
wherein the first electrode is electrically connected to the first terminal electrode through a connection layer.

3. The semiconductor device according to claim 1,
wherein the substrate is a glass substrate, a quartz substrate, a plastic substrate, or a semiconductor substrate.

4. The semiconductor device according to claim 1,
wherein the light-receiving element is a photodiode chip.

5. The semiconductor device according to claim 1, comprising:
a transistor comprising an oxide semiconductor layer over the substrate; and
a transistor comprising polycrystalline silicon.

6. The semiconductor device according to claim 1, further comprising:
a color conversion layer over the light-emitting diode,
wherein light emitted from the light-emitting diode passes through the color conversion layer.

7. A semiconductor device comprising:
a first light-emitting diode overlapping with a first region of a semiconductor substrate;
a second light-emitting diode overlapping with a second region of the semiconductor substrate; and
a third light-emitting diode overlapping with a third region of the semiconductor substrate,
wherein the semiconductor substrate comprises a fourth region which is adjacent to one or more of the first region, the second region, or the third region, and
wherein the fourth region of the semiconductor substrate comprises a photoelectric conversion layer and functions as a light-receiving element.

8. The semiconductor device according to claim 7, comprising:
a first electrode and a second electrode over the first region,
wherein the first light-emitting diode is a light-emitting diode chip, one terminal of the light-emitting diode chip being connected to the first electrode or the second electrode.

9. The semiconductor device according to claim 7,
wherein emission colors of the first light-emitting diode, the second light-emitting diode, and the third light-emitting diode are different from each other.

10. The semiconductor device according to claim 7, further comprising:
a color conversion layer over the second light-emitting diode,
wherein light emitted from the second light-emitting diode passes through the color conversion layer.
